(19) United States
(12) Patent Application Publication
(10) Pub. No.: US 2014/0151639 A1
(43) Pub. Date: Jun. 5, 2014

(54) NANOMESH COMPLEMENTARY METAL-OXIDE-SEMICONDUCTOR FIELD EFFECT TRANSISTORS

(71) Applicant: INTERNATIONAL BUSINESS MACHINES CORPORATION, (US)

(72) Inventors: Josephine B. Chang, Mahopac, NY (US); Paul Chang, Mahopac, NY (US); Michael A. Guillorn, Yorktown Heights, NY (US); Jeffrey W. Sleight, Ridgefield, CT (US)

(73) Assignee: INTERNATIONAL BUSINESS MACHINES CORPORATION, Armonk, NY (US)

(21) Appl. No.: 13/692,188

(22) Filed: Dec. 3, 2012

(51) Int. Cl. H01L 27/12; H01L 21/84

(52) U.S. Cl. CPC H01L 27/1211; H01L 21/845; B82Y 99/00
USPC 257/27; 438/154; 977/938; 977/888

(57) ABSTRACT

An alternating stack of first and second semiconductor layers is formed. Fin-defining mask structures are formed over the alternating stack. A planarization dielectric layer and first and second gate cavities therein are subsequently formed. The first and second gate cavities are extended downward by etching the alternating stack employing a combination of the planarization layer and the fin-defining mask structures as an etch mask. The germanium-free silicon material is isotropically etched to laterally expand the first gate cavity and to form a first array of semiconductor nanowires including the silicon-germanium alloy, and the silicon-germanium alloy is isotropically etched to laterally expand the second gate cavity and to form a second array of semiconductor nanowires including the germanium-free silicon material. The first and second gate cavities are filled with replacement gate structures. Each replacement gate structure laterally can surround a two-dimensional array of semiconductor nanowires.

### RELATED APPLICATIONS

The present application is related to co-assigned and co-pending U.S. application Ser. No. ______ (Attorney Docket No: YOR920120646US1; SSMP 29103), which is incorporated herein by reference.

### BACKGROUND

The present disclosure relates to a semiconductor structure, and particularly to nanomesh complementary metal-oxide-semiconductor field effect transistors (MOSFET's) and a method of manufacturing the same.

A silicon-germanium alloy channel is desirable for a p-type field effect transistor (PFET) and a silicon channel is desirable for an n-type field effect transistor (NFET). Particularly, a silicon-germanium alloy channel can provide enhance mobility and a valance band offset from the band gap structure of silicon. Thus, a PFET employing the silicon-germanium alloy channel can provide a lower threshold voltage than a PFET employing a silicon channel. However, such a change in the valence band offset in the silicon-germanium alloy degrades the threshold voltage of an NFET. Further, for undoped body fully depleted field effect transistors, threshold voltage adjustment is particularly challenging because doping cannot be used to tune the threshold voltage.

### BRIEF SUMMARY

An alternating stack of a silicon-germanium alloy and a germanium-free silicon material is formed by alternately growing epitaxial silicon-germanium alloy and the germanium-free silicon material on an silicon-on-insulator substrate. Fin-defining mask structures are formed over the alternating stack, and a first disposable gate structure and a second disposable gate structure are subsequently formed. After formation of a planarization dielectric layer, the first and second disposable gate structures are removed to form a first gate cavity and a second gate cavity, respectively. The first and second gate cavities are extended downward by etching the alternating stack employing a combination of the planarization layer and the fin-defining mask structures as an etch mask. Employing masked etch processes, the germanium-free silicon material is isotropically etched to laterally expand the first gate cavity and to form a first array of semiconductor nanowires including the silicon-germanium alloy, and the silicon-germanium alloy is isotropically etched to laterally expand the second gate cavity and to form a second array of semiconductor nanowires including the germanium-free silicon material. The first and second gate cavities are filled with replacement gate structures. Each replacement gate structure laterally can surround a two-dimensional array of semiconductor nanowires.

According to an aspect of the present disclosure, a method of forming a semiconductor structure is provided. An alternating stack of a silicon-germanium alloy and a germanium-free silicon material on an insulator layer is formed. A planarization dielectric layer including a first gate cavity and a second gate cavity is formed over the alternating stack. A plurality of first semiconductor nanowires including the silicon-germanium alloy is formed underneath the first gate cavity by patterning a first portion of the alternating stack. A plurality of second semiconductor nanowires including the germanium-free silicon material is formed underneath the second gate cavity by patterning a second portion of the alternating stack.

According to another aspect of the present disclosure, a semiconductor structure including a first field effect transistor and a second field effect transistor is provided. The first field effect transistor includes a first source region including a first alternating stack of a silicon-germanium alloy and a germanium-free silicon material, a first drain region including a second alternating stack of the silicon-germanium alloy and the germanium-free silicon material, a plurality of first channels located within a plurality of first semiconductor nanowires including the silicon-germanium alloy and extending between the first source region and the first drain region, and a first gate electrode surrounding each of the first plurality of semiconductor nanowires. The second field effect transistor includes a second source region including a third alternating stack of the silicon-germanium alloy and the germanium-free silicon material, a second drain region including a fourth alternating stack of the silicon-germanium alloy and the germanium-free silicon material, a plurality of second channels located within a plurality of second semiconductor nanowires including the germanium-free silicon material and extending between the second source region and the second drain region, and a second gate electrode surrounding each of the second plurality of semiconductor nanowires.

### BRIEF DESCRIPTION OF SEVERAL VIEWS OF THE DRAWINGS

FIG. 1A is a top-down view of an exemplary semiconductor structure after formation of an alternating stack of a silicon-germanium alloy and a germanium-free silicon material on an insulator layer according to an embodiment of the present disclosure.

FIG. 1B is a vertical cross-sectional view of the exemplary semiconductor structure along the vertical plane B-B′ of FIG. 1A.

FIG. 2A is a top-down view of the exemplary semiconductor structure after forming of a shallow trench isolation structure according to an embodiment of the present disclosure.

FIG. 2B is a vertical cross-sectional view of the exemplary semiconductor structure along the vertical plane B-B′ of FIG. 2A.

FIG. 3A is a top-down view of the exemplary semiconductor structure after formation of a plurality of fin-defining mask structures according to an embodiment of the present disclosure.

FIG. 3B is a vertical cross-sectional view of the exemplary semiconductor structure along the vertical plane B-B′ of FIG. 3A.

FIG. 4A is a top-down view of the exemplary semiconductor structure after formation of disposable gate structures and source and drain regions according to an embodiment of the present disclosure.

FIG. 4B is a vertical cross-sectional view of the exemplary semiconductor structure along the vertical plane B-B′ of FIG. 4A.

FIG. 5A is a top-down view of the exemplary semiconductor structure after formation of a planarization dielectric layer according to an embodiment of the present disclosure.

FIG. 5B is a vertical cross-sectional view of the exemplary semiconductor structure along the vertical plane B-B′ of FIG. 5A.

FIG. 6A is a top-down view of the exemplary semiconductor structure after removal of the first disposable gate structure according to an embodiment of the present disclosure.

FIG. 6B is a vertical cross-sectional view of the exemplary semiconductor structure along the vertical plane B-B′ of FIG. 6A.

FIG. 6C is a vertical cross-sectional view of the exemplary semiconductor structure along the vertical plane C-C′ of FIG. 6A.

FIG. 7A is a top-down view of the exemplary semiconductor structure after vertical extension of first gate cavity according to an embodiment of the present disclosure.

FIG. 7B is a vertical cross-sectional view of the exemplary semiconductor structure along the vertical plane B-B′ of FIG. 7A.

FIG. 7C is a vertical cross-sectional view of the exemplary semiconductor structure along the vertical plane C-C′ of FIG. 7A.

FIG. 8A is a top-down view of the exemplary semiconductor structure after removal of physically exposed portions of the plurality of fin-defining mask structures within a first gate cavity according to an embodiment of the present disclosure.

FIG. 8B is a vertical cross-sectional view of the exemplary semiconductor structure along the vertical plane B-B′ of FIG. 8A.

FIG. 9A is a top-down view of the exemplary semiconductor structure after formation of a first gate spacer according to an embodiment of the present disclosure.

FIG. 9B is a vertical cross-sectional view of the exemplary semiconductor structure along the vertical plane B-B′ of FIG. 9A.

FIG. 9C is a vertical cross-sectional view of the exemplary semiconductor structure along the vertical plane C-C′ of FIG. 9A.

FIG. 10A is a top-down view of the exemplary semiconductor structure after a lateral etch of physically exposed portions of the germanium-free silicon material according to an embodiment of the present disclosure.

FIG. 10B is a vertical cross-sectional view of the exemplary semiconductor structure along the vertical plane B-B′ of FIG. 10A.

FIG. 11A is a top-down view of the exemplary semiconductor structure after formation of a first gate dielectric and a first gate electrodes according to an embodiment of the present disclosure.

FIG. 11B is a vertical cross-sectional view of the exemplary semiconductor structure along the vertical plane B-B′ of FIG. 11A.

FIG. 11C is a vertical cross-sectional view of the exemplary semiconductor structure along the vertical plane C-C′ of FIG. 11A.

FIG. 11D is a vertical cross-sectional view of the exemplary semiconductor structure along the vertical plane D-D′ of FIG. 11A.

FIG. 11E is a vertical cross-sectional view of the exemplary semiconductor structure along the vertical plane E-E′ of FIG. 11A.

FIG. 11F is a vertical cross-sectional view of the exemplary semiconductor structure along the vertical plane F-F′ of FIG. 11A.

FIG. 12A is a top-down view of the exemplary semiconductor structure after removal of the second disposable gate structure according to an embodiment of the present disclosure.

FIG. 12B is a vertical cross-sectional view of the exemplary semiconductor structure along the vertical plane B-B′ of FIG. 12A.

FIG. 12C is a vertical cross-sectional view of the exemplary semiconductor structure along the vertical plane C-C′ of FIG. 12A.

FIG. 13A is a top-down view of the exemplary semiconductor structure after vertical extension of second gate cavity according to an embodiment of the present disclosure.

FIG. 13B is a vertical cross-sectional view of the exemplary semiconductor structure along the vertical plane B-B′ of FIG. 13A.

FIG. 13C is a vertical cross-sectional view of the exemplary semiconductor structure along the vertical plane C-C′ of FIG. 13A.

FIG. 14A is a top-down view of the exemplary semiconductor structure after removal of physically exposed portions of the plurality of fin-defining mask structures within a second gate cavity according to an embodiment of the present disclosure.

FIG. 14B is a vertical cross-sectional view of the exemplary semiconductor structure along the vertical plane B-B′ of FIG. 14A.

FIG. 15A is a top-down view of the exemplary semiconductor structure after formation of a second gate spacer according to an embodiment of the present disclosure.

FIG. 15B is a vertical cross-sectional view of the exemplary semiconductor structure along the vertical plane B-B′ of FIG. 15A.

FIG. 15C is a vertical cross-sectional view of the exemplary semiconductor structure along the vertical plane C-C′ of FIG. 15A.

FIG. 16A is a top-down view of the exemplary semiconductor structure after a lateral etch of physically exposed portions of the silicon-germanium alloy according to an embodiment of the present disclosure.

FIG. 16B is a vertical cross-sectional view of the exemplary semiconductor structure along the vertical plane B-B′ of FIG. 16A.

FIG. 17A is a top-down view of the exemplary semiconductor structure after formation of gate dielectrics and gate electrodes according to an embodiment of the present disclosure.

FIG. 17B is a vertical cross-sectional view of the exemplary semiconductor structure along the vertical plane B-B′ of FIG. 17A.

FIG. 17C is a vertical cross-sectional view of the exemplary semiconductor structure along the vertical plane C-C′ of FIG. 17A.

FIG. 17D is a vertical cross-sectional view of the exemplary semiconductor structure along the vertical plane D-D′ of FIG. 17A.

FIG. 17E is a vertical cross-sectional view of the exemplary semiconductor structure along the vertical plane E-E′ of FIG. 17A.

FIG. 17F is a vertical cross-sectional view of the exemplary semiconductor structure along the vertical plane F-F′ of FIG. 17A.

FIG. 18A is a top-down view of the exemplary semiconductor structure after formation of a contact level dielectric layer and contact via structures therethrough according to an embodiment of the present disclosure.

FIG. 18B is a vertical cross-sectional view of the exemplary semiconductor structure along the vertical plane B-B′ of FIG. 18A.

### DETAILED DESCRIPTION

As stated above, the present disclosure relates to nanomesh complementary metal-oxide-semiconductor field effect transistors (MOSFET's) and a method of manufacturing the same. Aspects of the present disclosure are now described in detail with accompanying figures. It is noted that like reference numerals refer to like elements across different embodiments. The drawings are not necessarily drawn to scale.

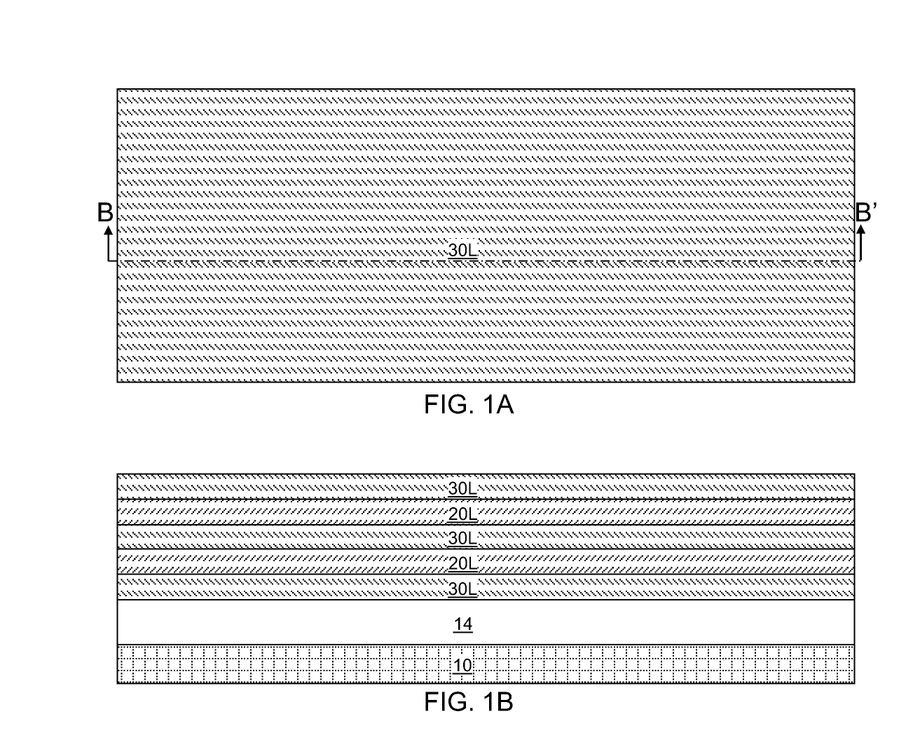

Referring to FIGS. 1A and 1B, an exemplary semiconductor structure according to an embodiment of the present disclosure includes a handle substrate 10, an insulator layer 14, and an alternating stack of a silicon-germanium alloy and a germanium-free silicon material. The handle substrate 10 can include a semiconductor material, an insulator material, a conductive material, or a combination thereof. The thickness of the handle substrate 10 can be from 50 microns to 2 mm, although lesser and greater thicknesses can also be employed. The handle substrate 14 provides mechanical support for the insulator layer 14 and the alternating stack.

The insulator layer 14 includes a dielectric material such as silicon oxide, silicon nitride, silicon oxynitride, or a combination thereof. The insulator layer 14 can have a thickness in a range from 5 nm to 500 nm, although lesser and greater thicknesses can also be employed. The insulator layer 10 can have a planar top surface.

The alternating stack includes at least one germanium-free silicon material layer 30L and at least one silicon-germanium alloy layer 20L. In one embodiment, the alternating stack can include a plurality of germanium-free silicon material layers 30L and a plurality of silicon-germanium alloy layers 20L. As used herein, a “germanium-free silicon material” refers to a semiconductor material consisting essentially of silicon and optionally one or more electrical dopants. The amount of germanium in a germanium-free silicon material is zero or below a trace level, i.e., below 1 p.p.b. (parts per billion). In one embodiment, the germanium-free silicon material can include more than 99% of silicon in atomic concentration.

The germanium-free silicon material is free of germanium. The bottommost layer among the germanium-free silicon material layer 30L can be provided as a single crystalline top semiconductor layer in a semiconductor-on-insulator (SOI) substrate. Other layers among the germanium-free silicon material layer 30L can be deposited as single crystalline semiconductor material layers in epitaxial alignment with an underlying silicon-germanium alloy layer 20L. Each germanium-free silicon material layer 30L is a single crystalline semiconductor material layer. Thus, the entirety of the alternating stack (20L, 30L) is single crystalline upon formation.

Specifically, each silicon-germanium alloy layer 20L can be deposited directly on the top surface of an underlying germanium-free silicon material layer 30L. Each silicon-germanium alloy layer 20L is epitaxially aligned to the single crystalline structure of the underlying germanium-free silicon material layer 30L. Each germanium-free silicon material layer 30L can be deposited directly on the top surface of an underlying single crystalline material layer, which can be one of the germanium-free silicon material layers 30L. Each germanium-free silicon material layer 30L is epitaxially aligned to the underlying single crystalline material layer.

Each of the silicon-germanium alloy layers 20L is deposited as a single crystalline semiconductor material layer in epitaxial alignment with an underlying germanium-free silicon material layer 30L. Each silicon-germanium alloy layer 20L is a single crystalline semiconductor material layer. The atomic concentration of germanium of each silicon-germanium alloy layer 20L can be in a range from 5% to 50%, although lesser and greater atomic concentrations of germanium can also be employed. In one embodiment, the atomic concentration of germanium can be the same across all of the silicon-germanium alloy layers 20L.

The thicknesses of the silicon-germanium alloy layers 20L and the germanium-free silicon material layers 30L are selected such that the entirety of the epitaxial alignment of the silicon-germanium alloy layers 20L and the germanium-free silicon material layers 30L can be maintained throughout the entirety of the alternating stack (20L, 30L). Thus, the thickness of each of the silicon-germanium alloy layers 20L and the germanium-free silicon material layers 30L is less than the critical thickness, which is the thickness at which an epitaxial material begins to lose epitaxial registry with the underlying single crystalline layer by developing dislocations.

In one embodiment, the germanium concentration in the silicon-germanium alloy layer 20L can be selected such that the thicknesses of each silicon-germanium alloy layer 20L and each germanium-free silicon material layer 30L can be in a range from 3 nm to 60 nm, although lesser and greater thicknesses can also be employed. In one embodiment, the thickness of the silicon-germanium alloy layers 20L can be the same. In this case, the thicknesses of each silicon-germanium alloy layer 20L is herein referred to as a first thickness. Additionally or alternatively, the thicknesses of the germanium-free silicon material layers 30L can be the same. In this case, the thickness of each germanium-free silicon material layer 30L is herein referred to as a second thickness.

The number of repetitions for a pair of a silicon-germanium alloy layer 20L and a germanium-free silicon material layer 30L can be 2 or greater. In one embodiment, the number of repetitions for a pair of a silicon-germanium alloy layer 20L and a germanium-free silicon material layer 30L can be in a range from, and including, 2 to, and including, 30. The alternating stack may begin, at the bottom, with a germanium-free silicon material layer 30L or with a silicon-germanium alloy layer 20L. Additionally, the alternating stack may terminate, at the top, with a germanium-free silicon material layer 30L or with a silicon-germanium alloy layer 20L.

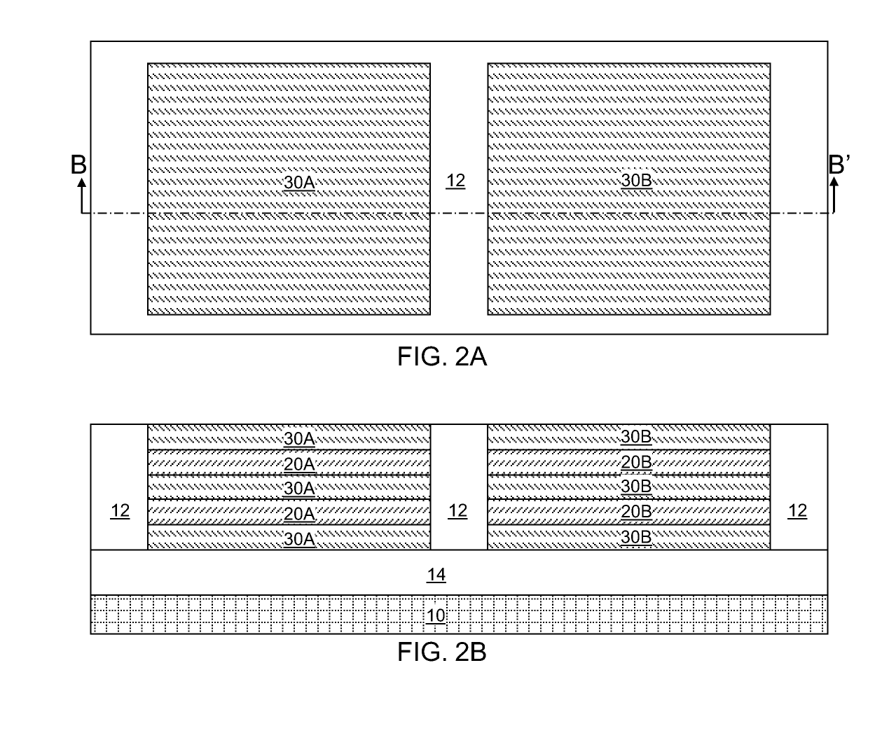

Referring to FIGS. 2A and 2B, a shallow trench isolation structure 12 including a dielectric material can be formed. Specifically, a shallow trench laterally enclosing at least one portion of the alternating stack (20L, 30L) can be formed by applying a photoresist layer (not shown) over the alternating stack (20L, 30L), by lithographically patterning the photoresist layer, and by transferring the pattern through the alternating stack (20L, 30L) and optionally an upper portion of the insulator layer 14 by an etch. The etch can be an anisotropic etch or an isotropic etch. The photoresist layer is subsequently removed, for example, by ashing.

At least one dielectric material such as silicon oxide, silicon nitride, and/or silicon oxynitride is deposited into the shallow trench. Excess dielectric material is removed from above the topmost surface of the remaining portion of the alternating stack (20L, 30L), for example, by chemical mechanical planarization (CMP). The remaining portions of the at least one dielectric material within the shallow trench constitute the shallow trench isolation structure 12.

In one embodiment, the shallow trench isolation structure 12 can laterally surround a first alternating stack of a first subset of remaining portions of the silicon-germanium alloy layer 20L and a first subset of remaining portions of the germanium-free silicon material layer 30L. The first subset of remaining portions of the silicon-germanium alloy layer 20L and the first subset of remaining portions of the germanium-free silicon material layer 30L can be doped with dopants of a first conductivity type prior to, or after, formation of the shallow trench isolation structure 12. The first conductivity type can be p-type or n-type.

The doping of the first subset of remaining portions of the silicon-germanium alloy layer 20L and the first subset of remaining portions of the germanium-free silicon material layer 30L can be performed by providing a dopant of the first conductivity type to a first portion of the alternating stack (20L, 30L) that includes the first alternating stack. In this case, the first subset of remaining portions of the silicon-germanium alloy layer 20L having a doping of the first conductivity type is referred to as first-conductivity-type silicon-germanium alloy layers 20A, and the first subset of remaining portions of the germanium-free silicon material layer 30L having a doping of the first conductivity type is herein referred to as first-conductivity-type germanium-free silicon material layers 30A. The first alternating stack (20A, 30A) includes the first-conductivity-type silicon-germanium alloy layers 20A and the first-conductivity-type germanium-free silicon material layers 30A. Alternately, the first alternating stack (20A, 30A) can remain undoped.

Further, the shallow trench isolation structure 12 can laterally surround a second alternating stack of a second subset of remaining portions of the silicon-germanium alloy layer 20L and a second subset of remaining portions of the germanium-free silicon material layer 30L. The second subset of remaining portions of the silicon-germanium alloy layer 20L and the second subset of remaining portions of the germanium-free silicon material layer 30L can be doped with dopants of a second conductivity type prior to, or after, formation of the shallow trench isolation structure 12. The second conductivity type is the opposite type of the first conductivity type. For example, if the first conductivity type is p-type, the second conductivity type is n-type, and vice versa.

The doping of the second subset of remaining portions of the silicon-germanium alloy layer 20L and the second subset of remaining portions of the germanium-free silicon material layer 30L can be performed by providing a dopant of the second conductivity type to a second portion of the alternating stack (20L, 30L) that includes the second alternating stack. In this case, the second subset of remaining portions of the silicon-germanium alloy layer 20L having a dopant of the second conductivity type is referred to as second-conductivity-type silicon-germanium alloy layers 20B, and the second subset of remaining portions of the germanium-free silicon material layer 30L having a doping of the second conductivity type is herein referred to as second-conductivity-type germanium-free silicon material layers 30B. The second alternating stack (20B, 30B) includes the second-conductivity-type silicon-germanium alloy layers 20B and the second-conductivity-type germanium-free silicon material layers 30B. Alternately, the second alternating stack (20B, 30B) can remain undoped.

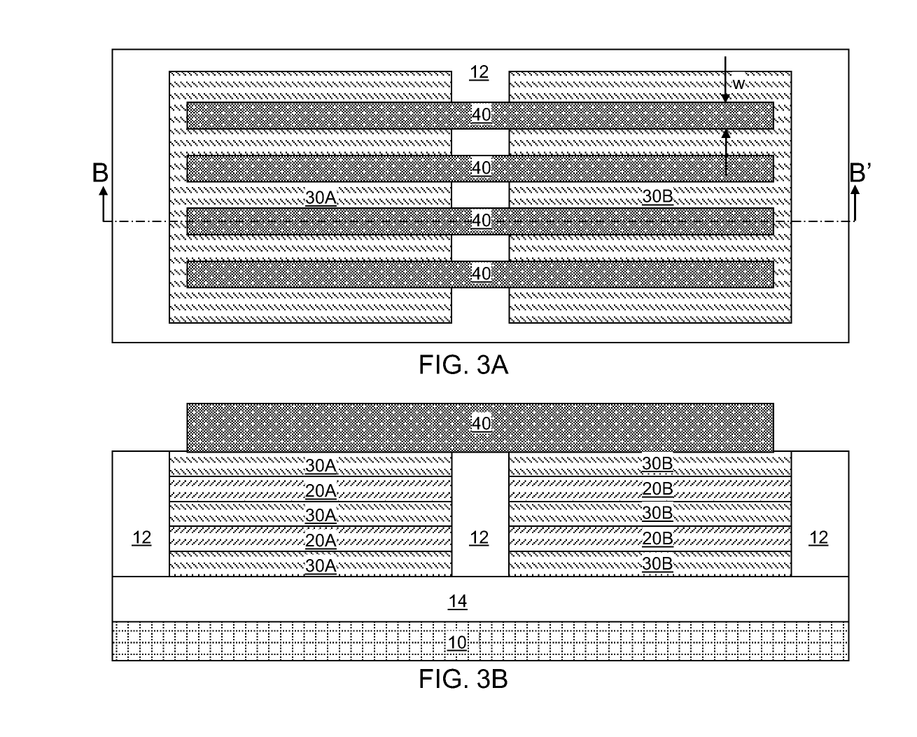

Referring to FIGS. 3A and 3B, an optional etch stop layer can be formed over the topmost surfaces of first alternating stack (20A, 20B) and the second alternating stack (20B, 30B). The optional etch stop layer, if present, can be subsequently employed as a stopping layer for an etch process. A plurality of fin-defining mask structures 40 is formed over the first alternating stack (20A, 30A) and the second alternating stack (20B, 30B). The plurality of fin-defining mask structures 40 can be mask structures that cover the regions of the first alternating stack (20A, 30A) and the second alternating stack (20B, 30B) in which field effect transistors are subsequently formed.

The plurality of fin-defining mask structures 40 can be formed, for example, by depositing a planar dielectric material layer and lithographically patterning the dielectric material layer. The planar dielectric material layer can be deposited, for example, by chemical vapor deposition (CVD). The planar dielectric material layer can include a dielectric material such as silicon nitride, silicon oxide, silicon oxynitride, a dielectric metal oxide, a dielectric metal nitride, or a dielectric metal oxynitride. The thickness of the planar dielectric material layer can be from 5 nm to 300 nm, although lesser and greater thicknesses can also be employed. The planar dielectric material layer can be subsequently patterned to form the plurality of fin-defining mask structures 40.

In one embodiment, each fin-defining mask structure 40 in the plurality of fin-defining mask structures 40 can laterally extend along a lengthwise direction. Further, each fin-defining mask structure 40 in the plurality of fin-defining mask structures 40 can have a pair of sidewalls that are separated along a widthwise direction, which is perpendicular to the lengthwise direction. In one embodiment, each fin-defining mask structure 40 in the plurality of fin-defining mask structures 40 can have a rectangular horizontal cross-sectional area. In one embodiment, the fin-defining mask structures 40 in the plurality of fin-defining mask structures 40 can have the same width w.

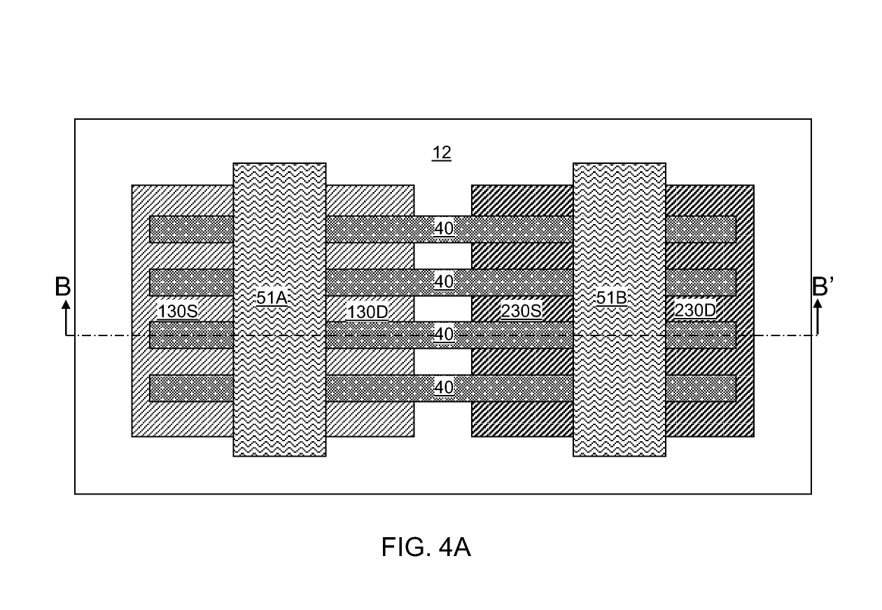

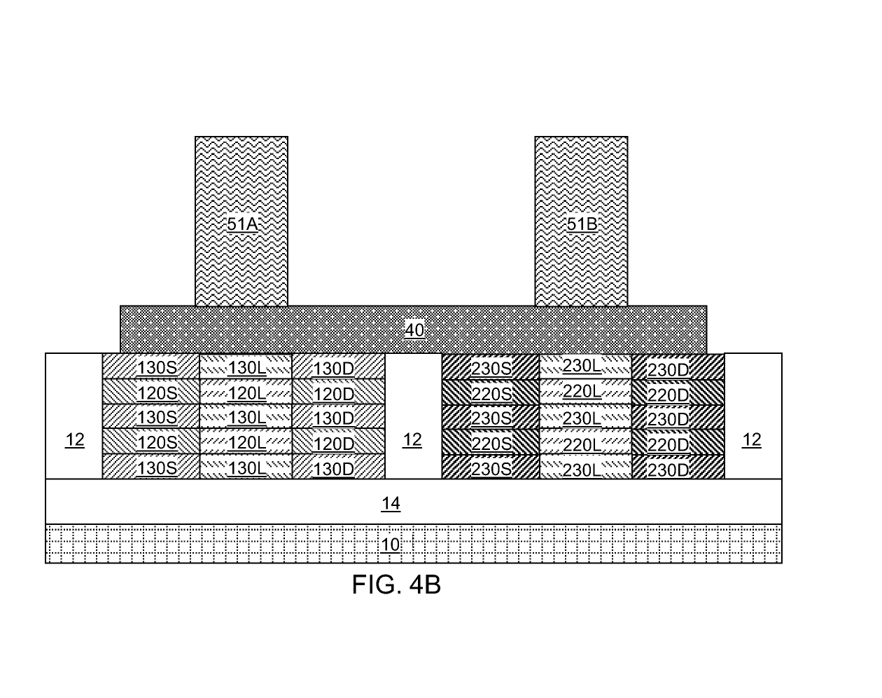

Referring to FIGS. 4A and 4B, disposable gate structures (51A, 51B) can be formed, for example, by depositing a disposable gate material layer stack (not shown), subsequently lithographically patterning the disposable gate material layer stack, and optionally depositing and patterning spacers on the sidewalls of the patterned disposable gate material stack. Remaining portions of the disposable gate material layer after the lithographic patterning along with the optional spacer constitute the disposable gate structures (51A, 51B).

The disposable gate material layer includes a material that can be removed selective to the material of the plurality of fin-defining mask structures 40. It may also include a capping layer such as silicon nitride. The disposable gate material layer can be deposited, for example, by chemical vapor deposition (CVD). The thickness of the disposable gate material layer, as measured above a planar surface, can be from 50 nm to 600 nm, although lesser and greater thicknesses can also be employed.

A photoresist layer (not shown) can be applied over the disposable gate material layer. The photoresist layer can be subsequently patterned into gate patterns, which are typically a plurality of lines which run perpendicular to and intersect the plurality of fin-defining mask structures 40. Physically exposed portions of the disposable gate material layer, i.e., portions of the disposable gate material layer that are not covered by the patterned photoresist layer, are removed, for example, by an etch, which can be an anisotropic etch. The etch that removes physically exposed portions of the disposable gate material layer can be selective to the materials of the plurality of fin-defining mask structures 40 and selective to the material of the topmost semiconductor layers, which can be the germanium-free silicon material layers (30A, 30B) or silicon-germanium alloy layers (20A, 20B). Alternately, the exposed region of fin-defining mask structures 40 may be removed during the gate etch or spacer etch.

If the optional etch stop layer is present, the etch that removes physically exposed portions of the disposable gate material layer can be selective to the materials of the optional etch stop layer. If the optional dielectric pad layer 40L is not present, the etch that removes physically exposed portions of the disposable gate material layer can be selective to the topmost semiconductor material of the first alternating stack (20A, 30A) and the second alternating stack (20B, 30B). The disposable gate structures 51 straddles over middle portions of the plurality of fin-defining mask structures 40. A spacer material layer (not shown) can be deposited conformally over the patterned disposable gate structures 51 and then etched anisotropically to leave spacers on the sidewalls of the gate structures.

Source and drain regions can be formed by implanting dopants into the first alternating stack (20A, 30A) and the second alternating stack (20B, 30B) employing the disposable gate structures (51A, 51B) as self-aligned masking structures. The disposable gate structures (51A, 51B) include a first disposable gate structure 51A formed over the first alternating stack (20A, 30A) (which is a first portion of the alternating stack (20L, 30L)) and a second disposable gate structure 51B formed over the second alternating stack (20B, 30B) (which is a second portion of the alternating stack (20L, 30L).

Sub-portions of the first alternating stack (20A, 30A) that are not masked with the first disposable gate structure 51A are engineered to form a first source region (120S, 130S) and a first drain region (120D, 130D). This may be accomplished by implanting with dopants of the second conductivity, using the first disposable gate structure 51A as an implantation mask during the ion implantation that forms the first source region (120S, 130S) and the first drain region (120D, 130D). Alternately, the first disposable gate structure 51A may be used as an etch mask to etch away portions of the first source region (120S, 130S) and the first drain region (120D, 130D), and an embedded material may be regrown in its place with selective epitaxy. This embedded material may be doped with the second conductivity type either during epitaxial grown or afterwards using ion implantation. The second alternating stack (20B, 30B) can be masked within a patterned masking layer (which can be a patterned photoresist layer) during the processes that form the first source region (120S, 130S) and the first drain region (120D, 130D).

The first source region (120S, 130S) includes an alternating stack of first material first source regions 120S and second material first source regions 130S. The first source region (120S, 130S) is a first subset of the alternating stack (20L, 30L; See FIG. 1B). The first drain region (120D, 130D) includes an alternating stack of first material first drain regions 120D and second material first drain regions 130D. The first drain region (120D, 130D) is a second subset of the alternating stack (20L, 30L; See FIG. 1B).

The first source region (120S, 130S) and the first drain region (120D, 130D) can have a doping of the second conductivity type. The portions of the first alternating stack (20A, 30A) that are not doped with dopants of the second conductivity type, and thus, can have a doping of the first conductivity type, include a vertical stack of first material first conductivity type layers 120L and second material first conductivity type layers 130L. Each first material first conductivity type layer 120L includes the silicon-germanium alloy and can have a doping of the first conductivity type, and each second material first conductivity type layer 130L includes the germanium-free silicon material and can have a doping of the first conductivity type. A junction is formed between the first source region (120S, 130S) and the vertical stack of first material first conductivity type layers 120L and second material first conductivity type layers 130L. Another junction is formed between the first drain region (120D, 130D) and the vertical stack of first material first conductivity type layers 120L and second material first conductivity type layers 130L. In one embodiment, the junctions can be p-n junctions. In another embodiment, the vertical stack of first material first conductivity type layers 120L and second material first conductivity type layers 130L can include intrinsic semiconductor materials, and the junctions can be between doped semiconductor materials and intrinsic semiconductor materials.

Sub-portions of the second alternating stack (20B, 30B) that are not masked with the second disposable gate structure 51B are engineered to form a second source region (220S, 230S) and a second drain region (220D, 230D). This may be accomplished by implanting with dopants of the first conductivity, using the second disposable gate structure 51B as an implantation mask during the ion implantation that forms the second source region (220S, 230S) and the second drain region (220D, 230D). Alternately, the second disposable gate structure 51B may be used as an etch mask to etch away portions of the second source region (220S, 230S) and the second drain region (220D, 230D), and an embedded material may be regrown in its place with selective epitaxy. This embedded material may be doped with the first conductivity type either during epitaxial grown or afterwards using ion implantation. The first alternating stack (20A, 30A) can be masked within a patterned masking layer (which can be a patterned photoresist layer) during the processes that form the second source region (220S, 230S) and the second drain region (220D, 230D).

The second source region (220S, 230S) includes an alternating stack of first material second source regions 220S and second material second source regions 230S. The second source region (220S, 230S) is a third subset of the alternating stack (20L, 30L; See FIG. 1B). The second drain region (220D, 230D) includes an alternating stack of first material second drain regions 220D and second material second drain regions 230D. The second drain region (220D, 230D) is a fourth subset of the alternating stack (20L, 30L; See FIG. 1B).

The second source region (220S, 230S) and the second drain region (220D, 230D) can have a doping of the first conductivity type. The portions of the second alternating stack (20B, 30B) that are not doped with dopants of the first conductivity type, and thus, can have a doping of the second conductivity type, include a vertical stack of first material second conductivity type layers 220L and second material second conductivity type layers 230L. Each first material second conductivity type layer 220L includes the silicon-germanium alloy and can have a doping of the second conductivity type, and each second material second conductivity type layer 230L includes the germanium-free silicon material and can have a doping of the second conductivity type. A junction is formed between the second source region (220S, 230S) and the vertical stack of first material second conductivity type layers 220L and second material second conductivity type layers 230L. Another junction is formed between the second drain region (220D, 230D) and the vertical stack of first material second conductivity type layers 220L and second material second conductivity type layers 230L. In one embodiment, the junctions can be p-n junctions. In another embodiment, the vertical stack of first material first conductivity type layers 120L and second material first conductivity type layers 130L can include intrinsic semiconductor materials, and the junctions can be between doped semiconductor materials and intrinsic semiconductor materials.

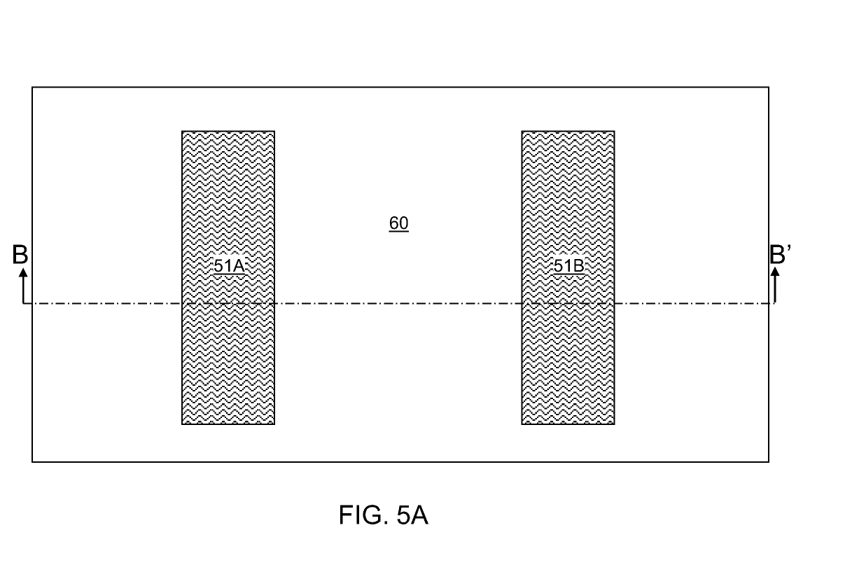

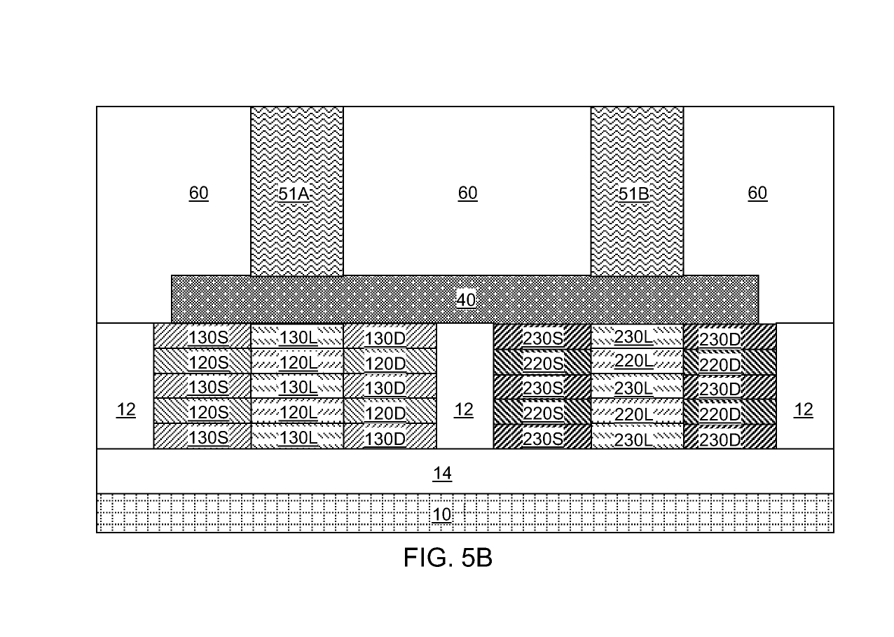

Referring to FIGS. 5A and 5B, a planarization dielectric layer 60 is formed over the first and second alternating stacks and the plurality of fin-defining mask structures 40. The planarization dielectric layer 60 can be formed, for example, by depositing a dielectric material over the first and second alternating stacks, the plurality of fin-defining mask structures 40, and the first and second disposable gate structures (51A, 51B), and subsequently planarizing the dielectric material to form a planar top surface that is coplanar with the top surfaces of remaining portions of the first and second disposable gate structures (51A, 51B). Alternately, the planarization dielectric layer 60 can include a self-planarizing dielectric material. In this case, the deposition and planarization of the dielectric material for formation of the planarization dielectric layer 60 can be performed simultaneously. The dielectric material of the planarization dielectric layer 60 can include, for example, silicon oxide, silicon nitride, silicon oxynitride, organosilicate glass, and/or a spin-on dielectric material.

Because of the presence of the first and second disposable gate structures (51A, 51B), the planarization dielectric layer 60 includes a first hole corresponding to the volume of the first disposable gate structure 51A and a second hole corresponding to the volume of the second disposable gate structure 51B.

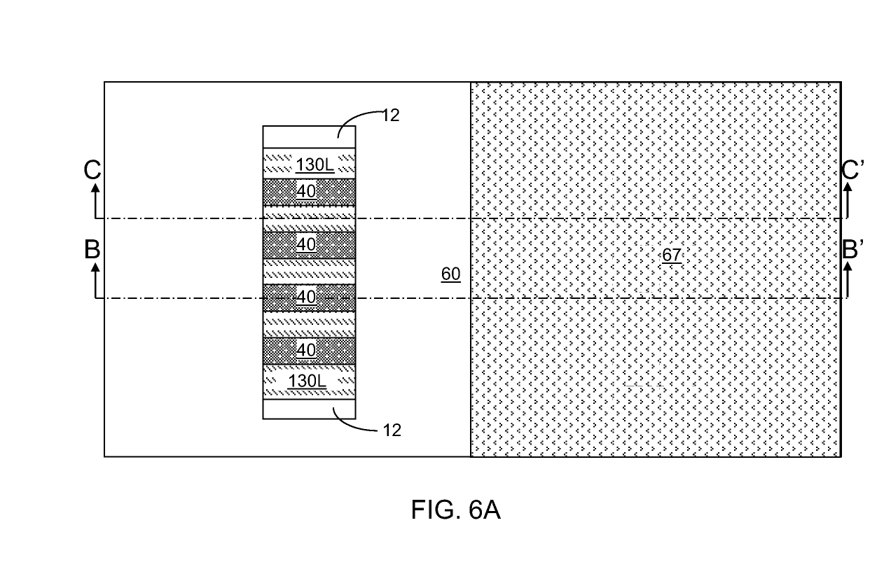

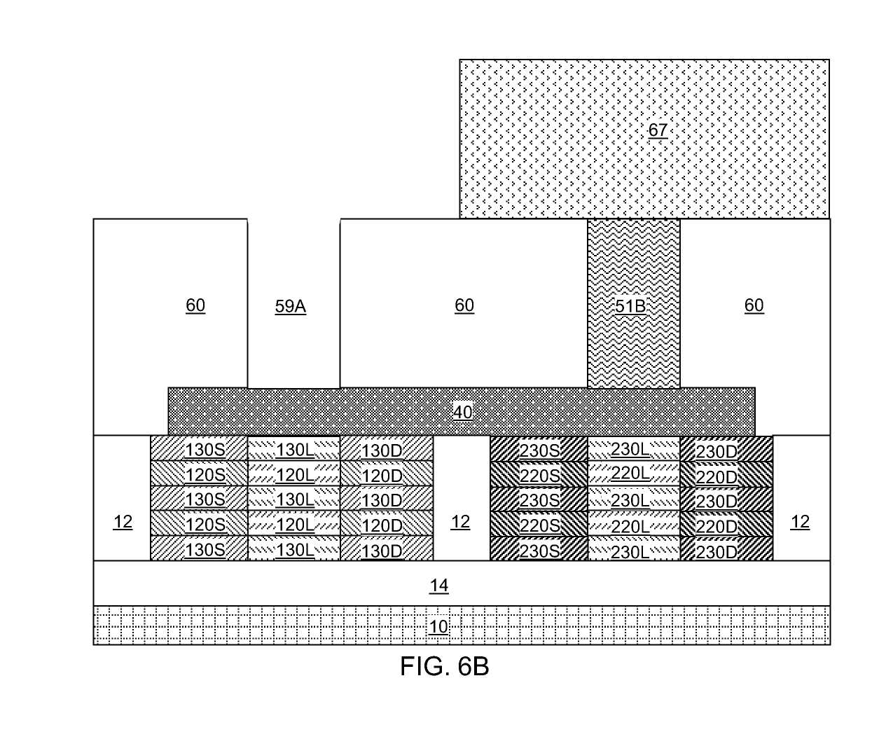

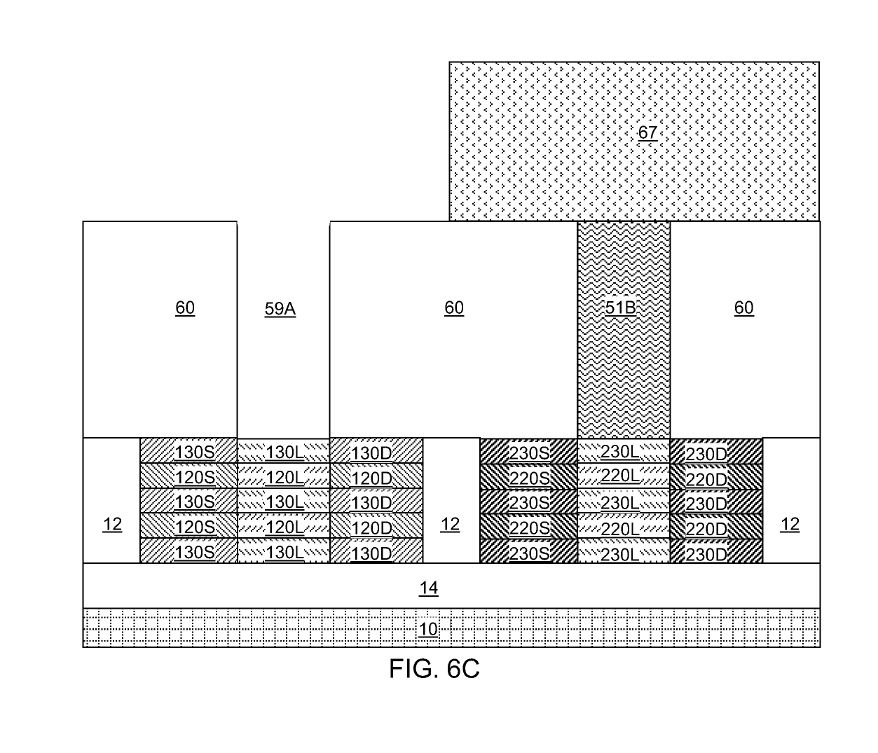

Referring to FIGS. 6A, 6B, and 6C, a first masking layer 67 is formed above the second disposable gate structure 51B, while physically exposing a top surface of the first disposable gate structure 51A. The first masking layer 67 can be a lithographically patterned photoresist layer. The first disposable gate structure 51A is removed selective to the planarization dielectric layer 60 and the topmost semiconductor material in the first alternating stack. A first gate cavity 59A is formed in the volume from which the first disposable gate structure 51A is removed. The planarization dielectric layer 60 includes a first gate cavity 59A that is located over the first alternating stack. The first masking layer 67 may be subsequently removed, for example, by ashing, or may remain above the second disposable gate structure 51B.

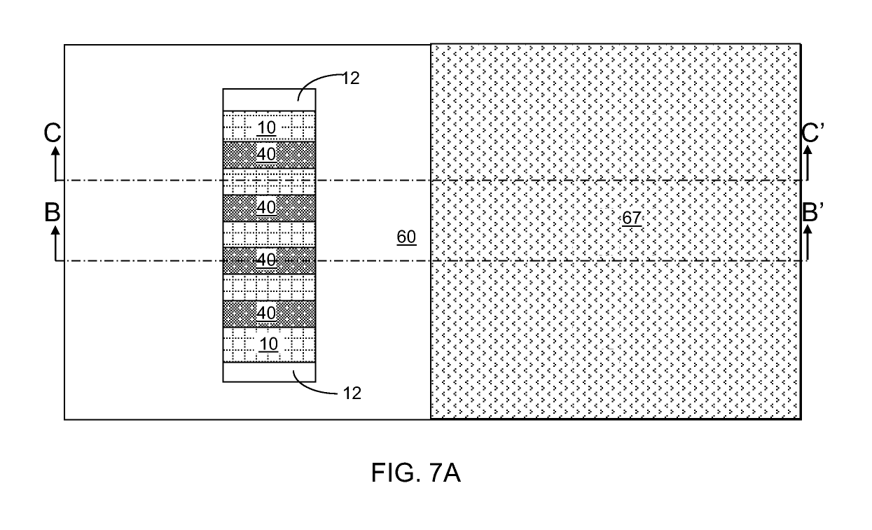

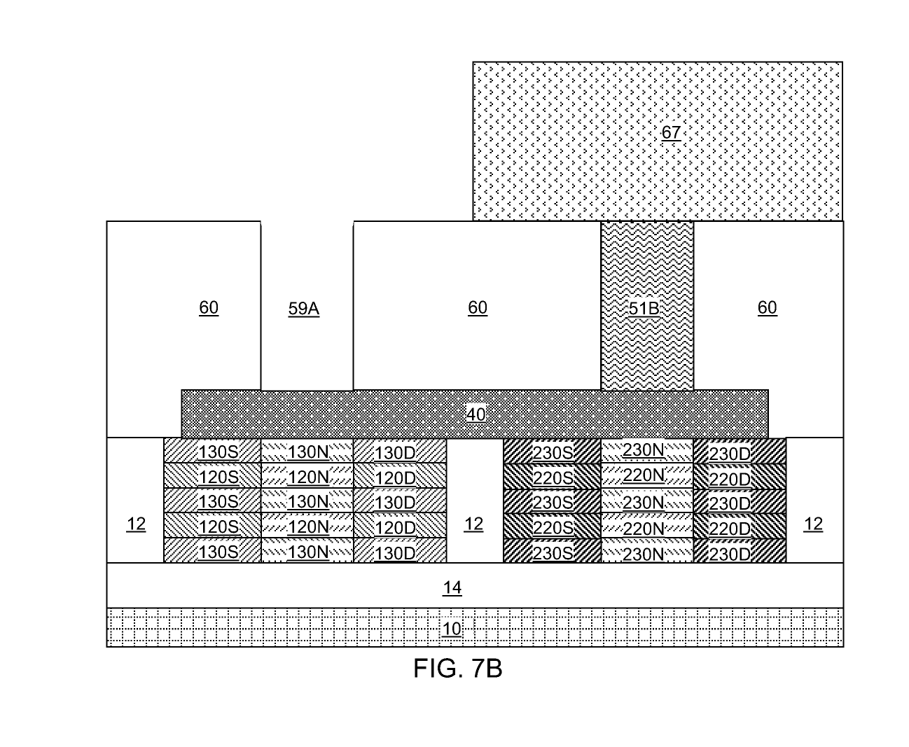

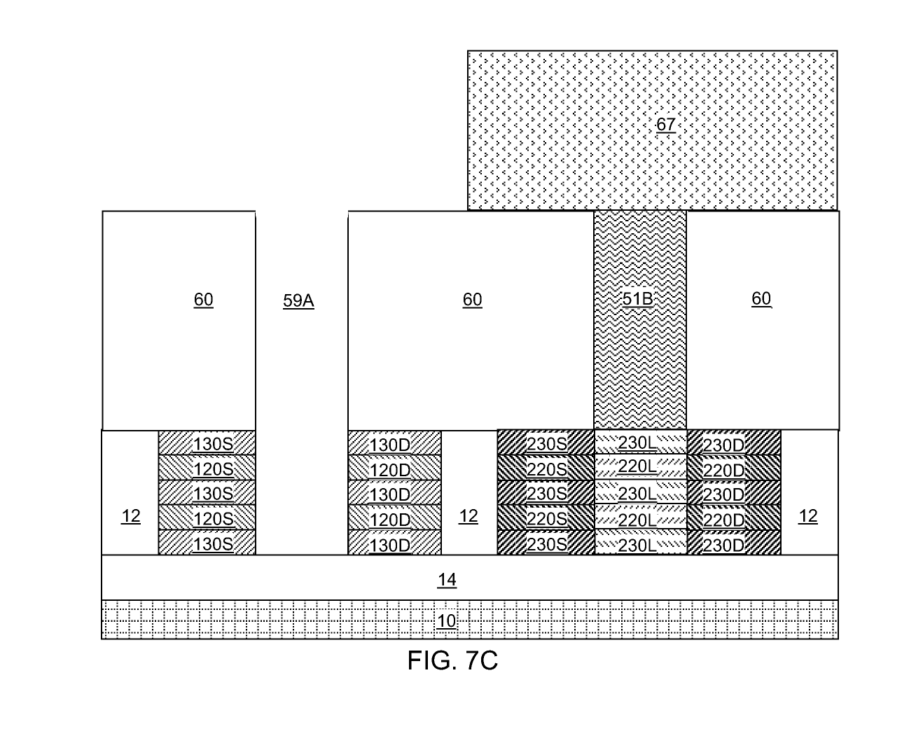

Referring to FIGS. 7A, 7B, and 7C, the first gate cavity 59A is vertically extended downward by anisotropically etching the first alternating stack employing the combination of the planarization dielectric layer 60 and the plurality of fin-defining mask structures 40 as an etch mask. Thus, the first gate cavity 59A is vertically extended only within regions that are not blocked by the plurality of fin-defining mask structures 40. The first gate cavity 59A can be vertically extended downward at least to the top surface of the insulator layer 14.

The remaining portions of the vertical stack of first material first conductivity type layers 120L and second material first conductivity type layers 130L form a plurality of first vertical stacks of nanowires (120N, 130N). As used herein, a “nanowire” refers to a structure having lateral dimensions not exceeding 100 nm and extending along a lengthwise direction for a distance greater than any widthwise dimension. Each first vertical stack of nanowires (120N, 130N) includes first material first conductivity type nanowires 120N and second material first conductivity type nanowires 130N. Each first material first conductivity type nanowire 120N includes the silicon-germanium alloy and can have a doping of the first conductivity type, and each second material first conductivity type nanowire 130N includes the germanium-free silicon material and can have a doping of the first conductivity type. A junction is present between the first source region (120S, 130S) and each first vertical stack of nanowires (120N, 130N). Another junction is formed between the first drain region (120D, 130D) and each first vertical stack of nanowires (120N, 130N). In one embodiment, the junctions can be p-n junctions. In another embodiment, the junctions can be between doped semiconductor materials and intrinsic semiconductor materials.

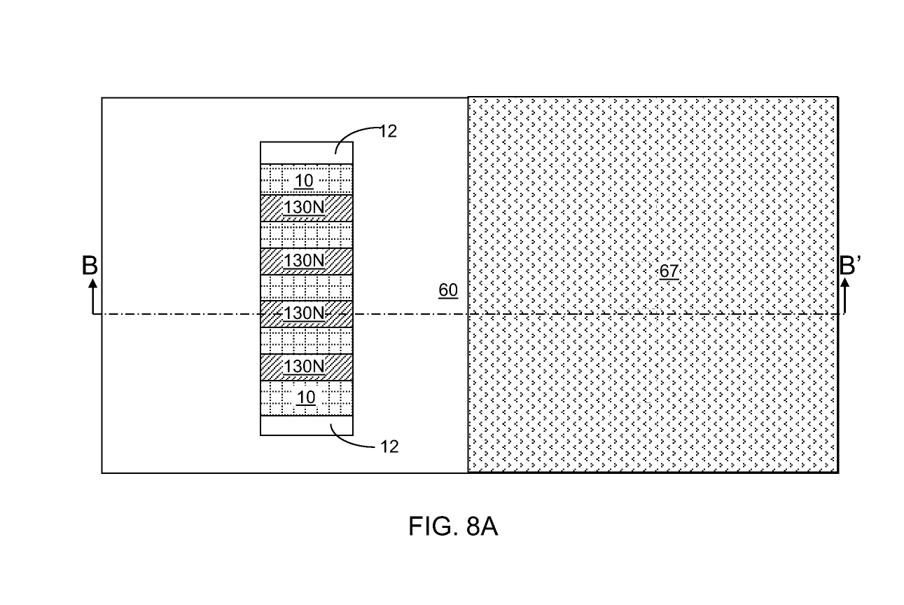

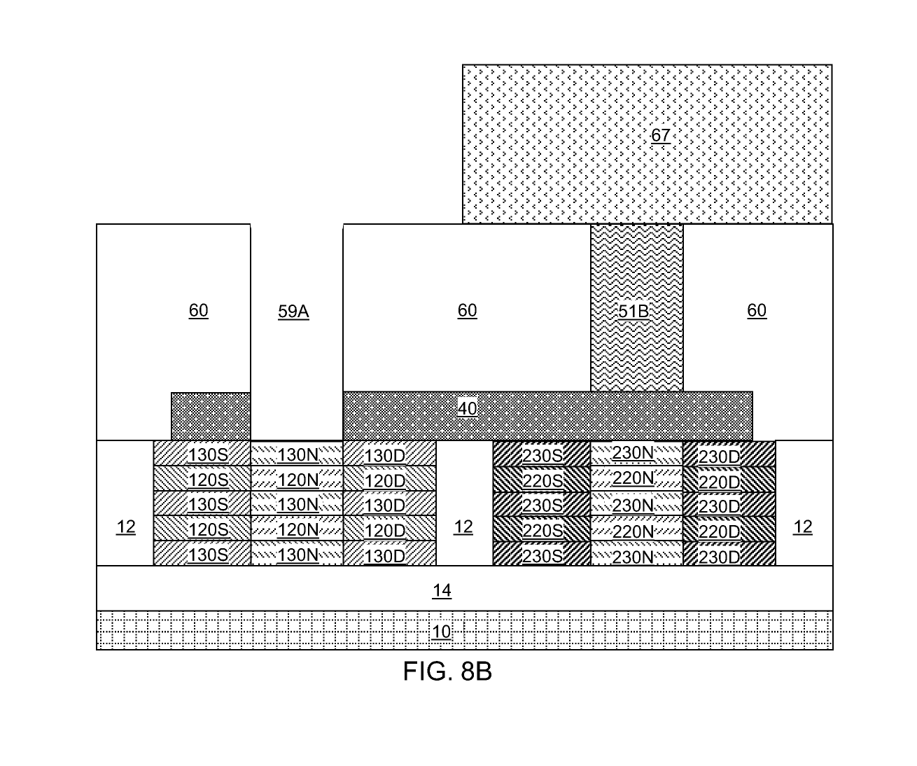

Referring to FIGS. 8A and 8B, physically exposed portions of the plurality of fin-defining mask structures 40 can be optionally removed by an etch, which can be an isotropic etch or an anisotropic etch. The removal of the physically exposed portions of the plurality of fin-defining mask structures 40 is performed selective to the plurality of first vertical stacks of nanowires (120N, 130N). For example, if the plurality of fin-defining mask structures 40 include silicon nitride, the removal of the physically exposed portions of the plurality of fin-defining mask structures 40 can be performed by a wet etch employing hot phosphoric acid. The first masking layer 67, if present, can be removed selective to the second disposable gate structure 51B, for example, by ashing. Alternately, the first masking layer 67 may remain above the second disposable gate structure 51B.

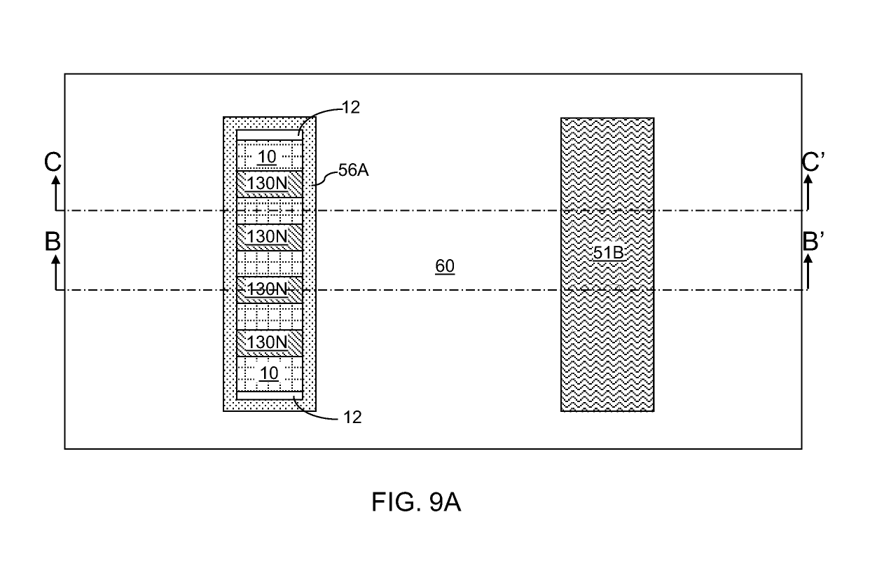

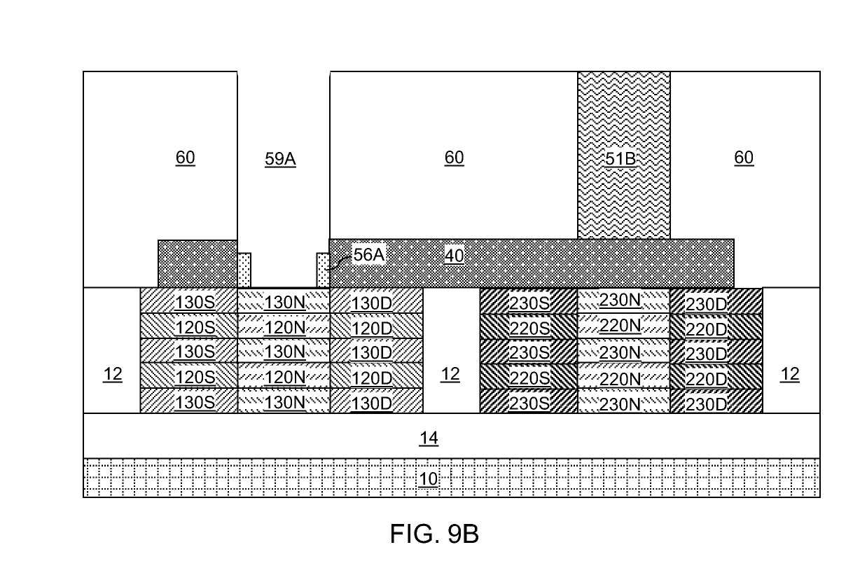

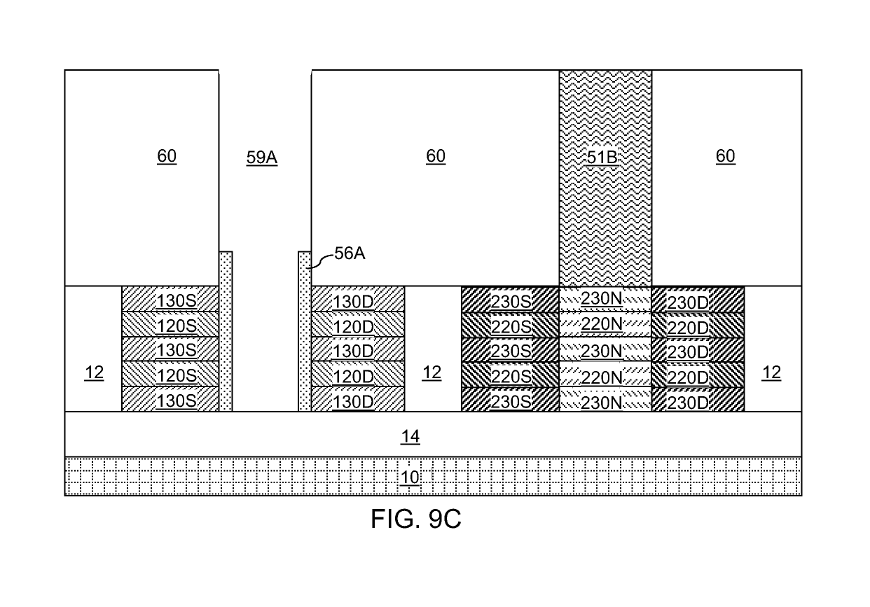

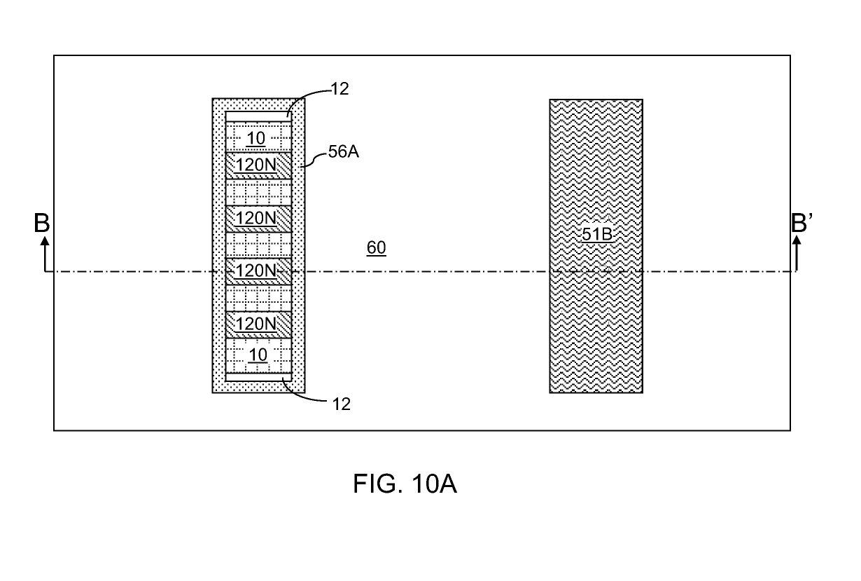

Referring to FIGS. 9A, 9B, and 9C, a first gate spacer 56A can be formed on sidewalls of the planarization dielectric layer 60 within the first gate cavity 59A. A conformal dielectric material layer (not shown) can be deposited, for example, by chemical vapor deposition (CVD) or atomic layer deposition (ALD). The conformal dielectric material layer includes a dielectric material such as silicon nitride, silicon oxide, a dielectric metal oxide, or a combination thereof. The thickness of the conformal dielectric material layer can be from 3 nm to 100 nm, although lesser and greater thicknesses can also be employed.

The dielectric material of the conformal dielectric material layer may, or may not be, the same as the dielectric material of the plurality of fin-defining mask structures 40. In one embodiment, the dielectric material of the conformal dielectric material layer can be the same as the dielectric material of the plurality of fin-defining mask structures 40. In one embodiment, the dielectric material of the conformal dielectric material layer and the dielectric material of the plurality of fin-defining mask structures 40 can be silicon nitride. Vertical portions of the conformal dielectric material layer are subsequently etched by an anisotropic etch to form the first gate spacer 56A.

The first gate spacer 56A including a dielectric material can be formed on the sidewalls of the planarization dielectric layer 60 and sidewalls of remaining portions of the plurality of fin-defining mask structures 40 that are present within the vertically extended first gate cavity 59A. The first gate spacer 56A can include at least one vertical strip having a uniform width as illustrated in FIG. 9C. In one embodiment, the uniform width can be the same as the spacing between a neighboring pair of first vertical stacks of nanowires (120N, 130N).

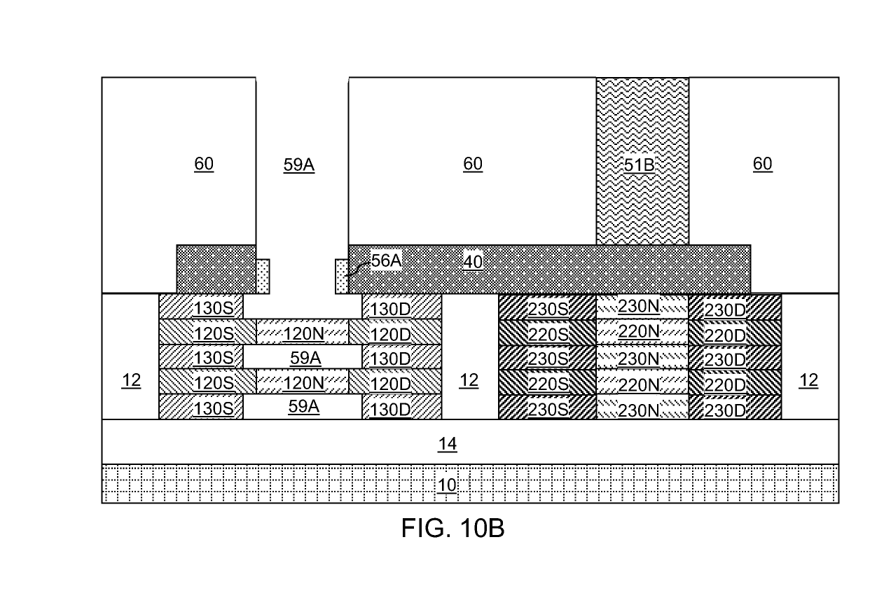

Referring to FIGS. 10A and 10B, a lateral etch of physically exposed portions of the germanium-free silicon material is performed selective to the silicon-germanium alloy. In one embodiment, removal of the germanium-free silicon material, i.e., a semiconductor material consisting essentially of silicon and optional electrical dopants (p-type dopants or n-type dopants) can be performed by an isotropic dry etch disclosed in V. Caubet et al., Mechanisms of isotropic and selective etching between SiGe and Si*, J. Vac. Sci. Technol. B 24(6), pp. 2748-2754 (2006). For example, a selectivity of about 100 can be obtained between the etch rate of a germanium-free silicon material and the etch rate of a silicon-germanium alloy including 20% Ge in atomic concentration in a dry etch chemistry employing a mixture of CF₄, N₂, O₂, and CH₂F₂. The dry etch chemistry can be implemented as a plasma etch, for example, at a pressure in a range from 300 mT to 1,500 mT. The ratio of flow rates among CF₄, N₂, O₂, and CH₂F₂ can be, for example, 3:2:5:1, although variations of the ratio can be employed provided that selectivity is present between removal of the germanium-free silicon material and removal of the silicon-germanium alloy.

Thus, the first gate cavity 59A is laterally expanded by removing the germanium-free silicon material selective to the silicon-germanium alloy while the second disposable gate structure 51B overlies the second alternating stack (220S, 230S, 220N, 230N, 220S, 230D). The second material first conductivity type nanowires 130N and physically exposed end sub-portions of the second material first source portions 130S and the second material first drain portions 130D are removed by the lateral etch. The first material first conductivity type nanowires 120N become suspended. The first material first conductivity type nanowires 120N constitute a plurality of first suspended semiconductor nanowires including the silicon-germanium alloy, and are located underneath the first gate cavity 59A as formed at the processing step of FIGS. 6A, 6B, and 6C.

Concurrently with removal of the germanium-free silicon material between first material first conductivity type nanowires 120N, portions of the germanium-free silicon material are laterally recessed along the lengthwise direction of the first material first conductivity type nanowires 120N. Thus, each nanowire including a first material first conductivity type nanowires 120N is extended along a lengthwise direction to include a portion of a first material first source region 120S and a portion of a first material first drain region 120D. Portions of p-n junctions or junctions between a doped portion and an intrinsic portion are physically exposed around each end portion of a semiconductor nanowire including the silicon-germanium alloy. The first masking layer 67, if present, may be removed selective to the second disposable gate structure 51B, for example, by ashing.

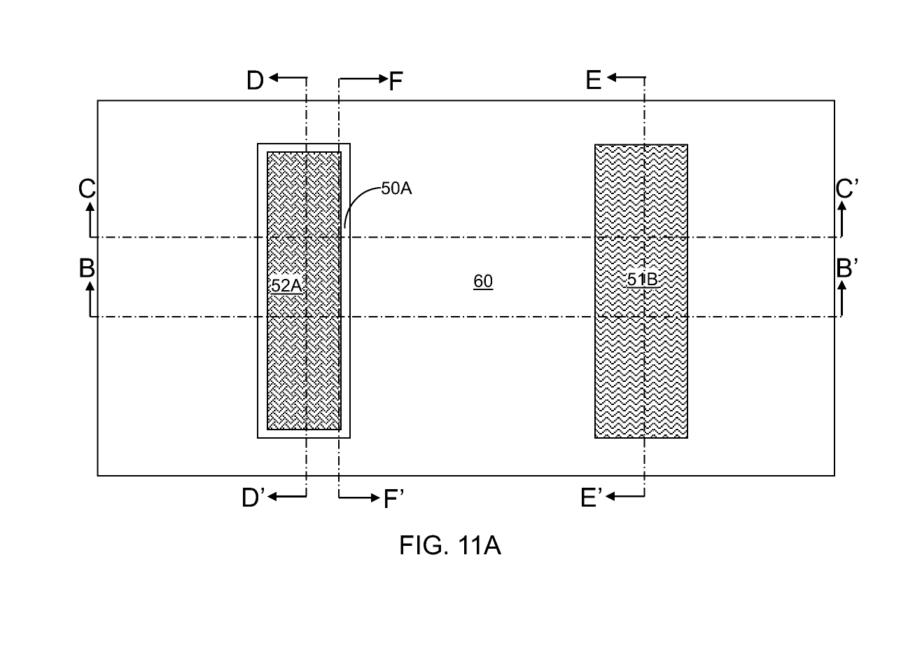

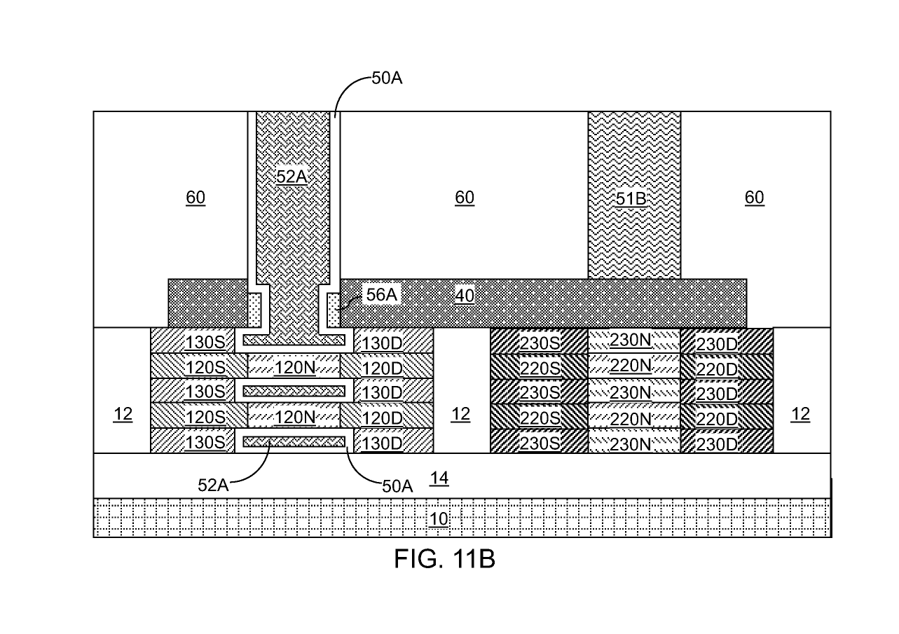

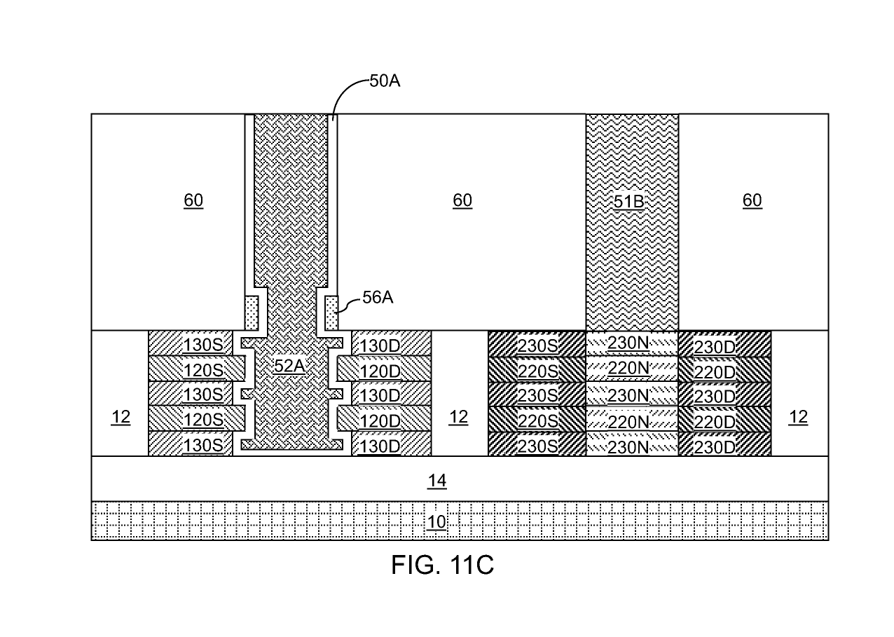

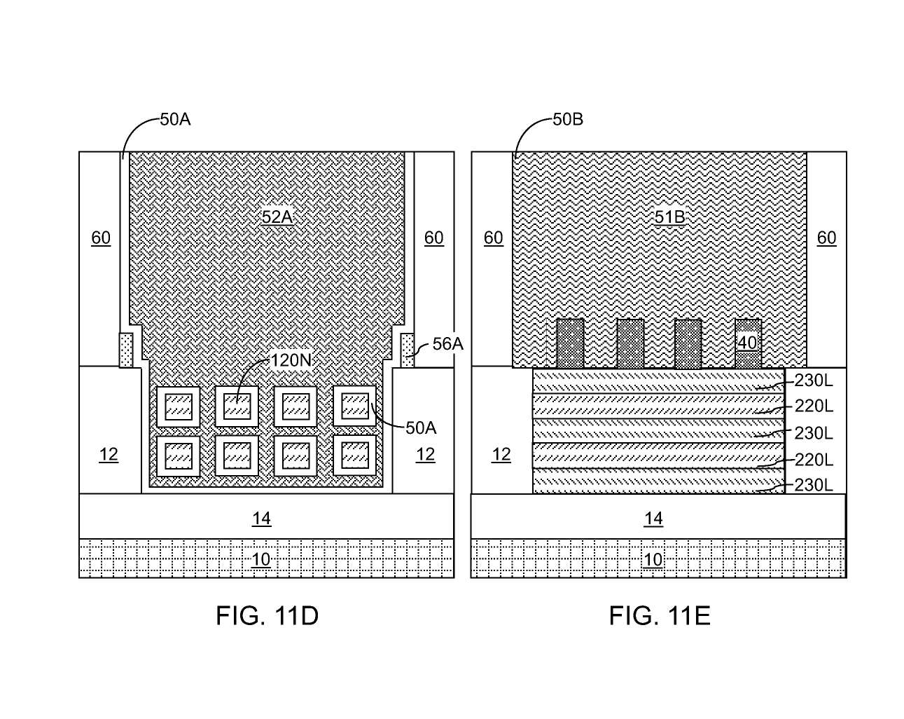

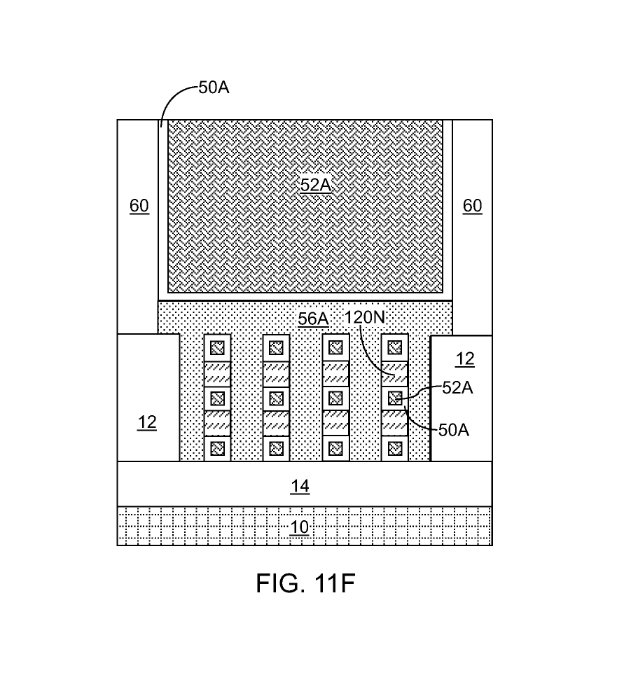

Referring to FIGS. 11A, 11B, 11C, 11D, 11E, and 11F, a first gate dielectric 50A and a first gate electrode 52A are formed within the first gate cavity 59A. The first gate dielectric 50A can be a contiguous structure, i.e., a contiguous gate dielectric. The first gate dielectric 50A and the first gate electrode 52A can be formed by depositing a stack of a gate dielectric layer and a gate conductor layer within the first gate cavity 59A, and removing portions of the gate dielectric layer and the gate conductor layer from above a top surface of the planarization dielectric layer 60.

Specifically, a gate dielectric layer can be deposited on physically exposed surfaces within the first gate cavity 59A and on the top surface of the planarization dielectric layer 60. The gate dielectric layer can include any gate dielectric material known in the art. Subsequently, a conductive material is deposited into the first gate cavity 59A. The conductive material, and optionally, the gate dielectric layer are subsequently planarized, for example, by chemical mechanical planarization (CMP). The remaining portion of the gate dielectric layer filling the first gate cavity 59A constitutes the first contiguous gate dielectric 50A, which is contiguous throughout the entirety thereof. The remaining portion of the conductive material filling the first gate cavity 59A constitutes the first gate electrode 52A.

The first contiguous gate dielectric 50A is formed on all physically exposed surfaces of the plurality of first semiconductor wires that include first material first conductivity type nanowires 120N. The first gate electrode 52A is formed on the first contiguous gate dielectric 50A and within the first gate cavity 59A.

The first alternating stack, which is a first portion of the alternating stack (20L, 30L; See FIG. 1B), includes various sub-portions. The various sub-portions of the first alternating stack include the first source region (120S, 130S) including a first portion of the alternating stack (20L, 30L), and the first drain region (120D, 130D) including a second portion of the alternating stack (20L, 30L).

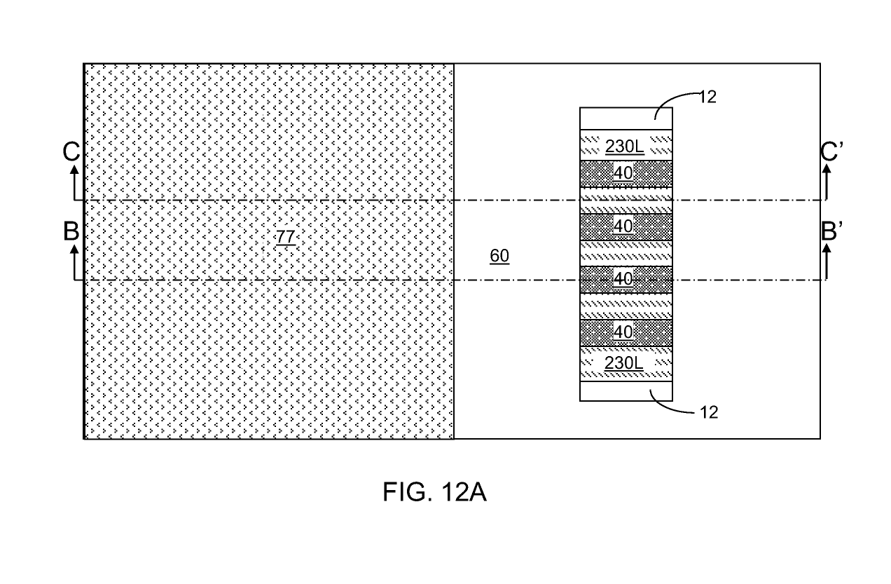

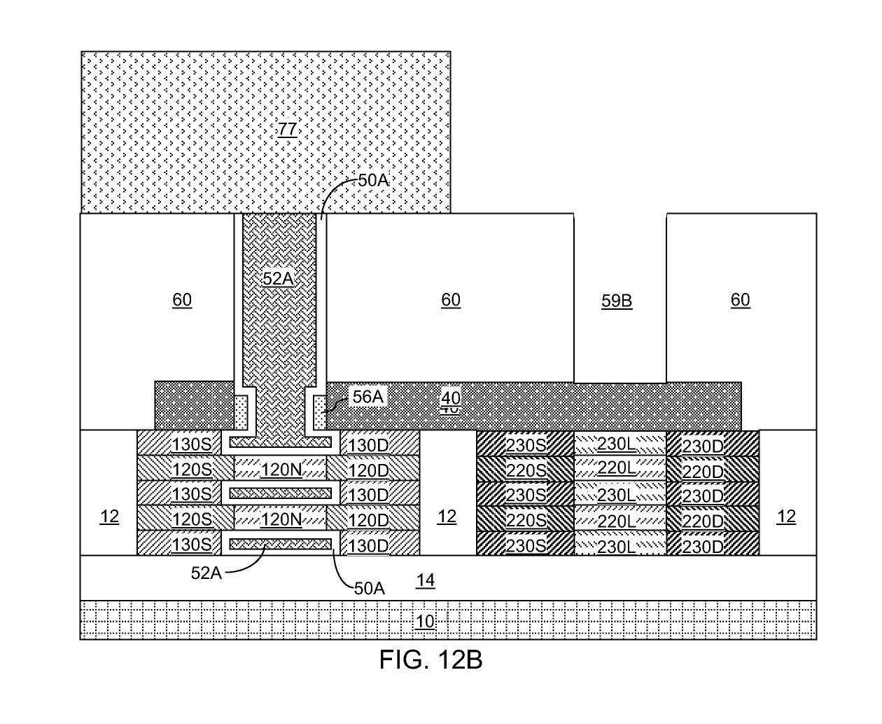

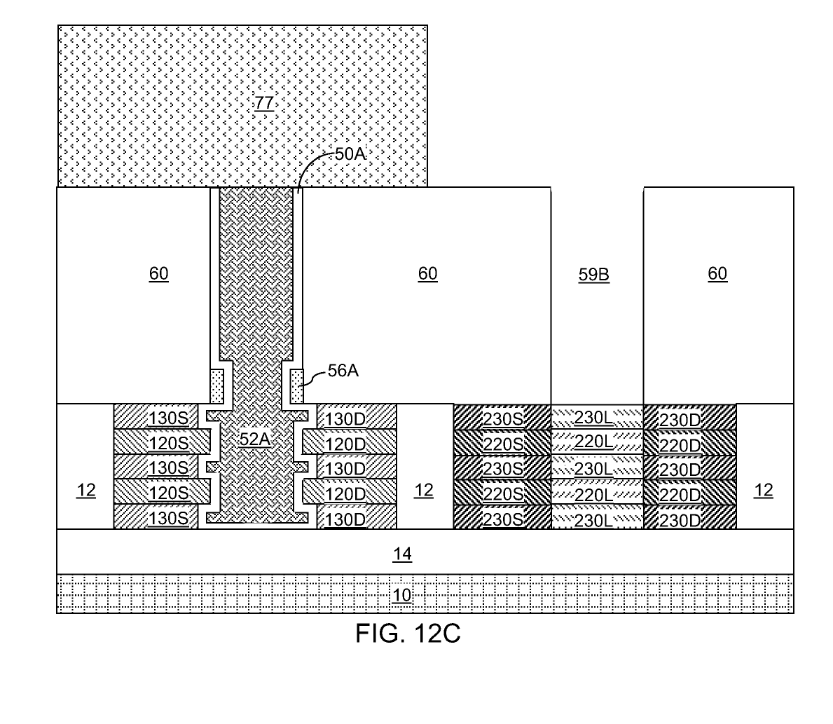

Referring to FIGS. 12A, 12B, and 12C, a second masking layer 77 is formed above the first gate electrode 52A while physically exposing a top surface of the second disposable gate structure 51B. The second masking layer 77 can be a lithographically patterned photoresist layer. The second disposable gate structure 51B is removed selective to the planarization dielectric layer 60 and the topmost semiconductor material in the second alternating stack. A second gate cavity 59B is formed in the volume from which the second disposable gate structure 51B is removed. The planarization dielectric layer 60 includes a second gate cavity 59B that is located over the first alternating stack. The second masking layer 77 may be subsequently removed, for example, by ashing, or may remain above the first gate electrode 52A.

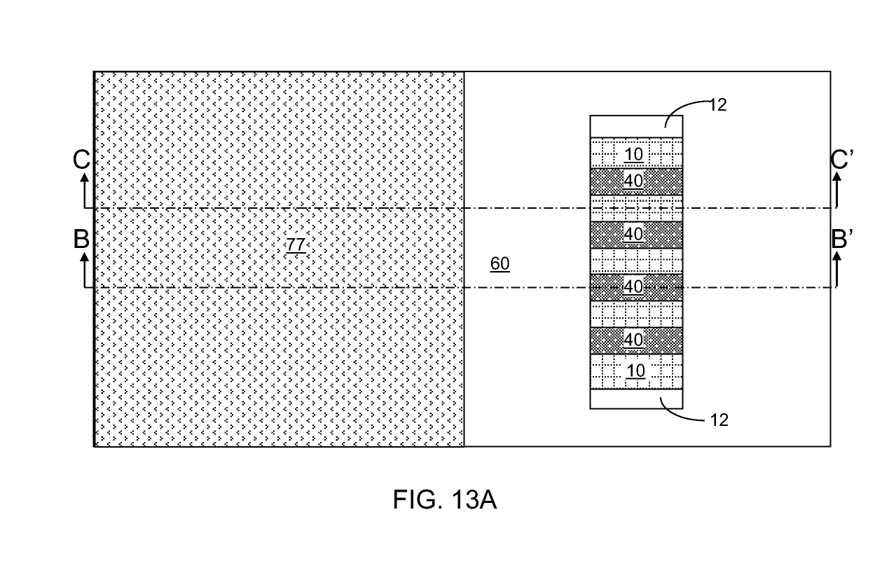

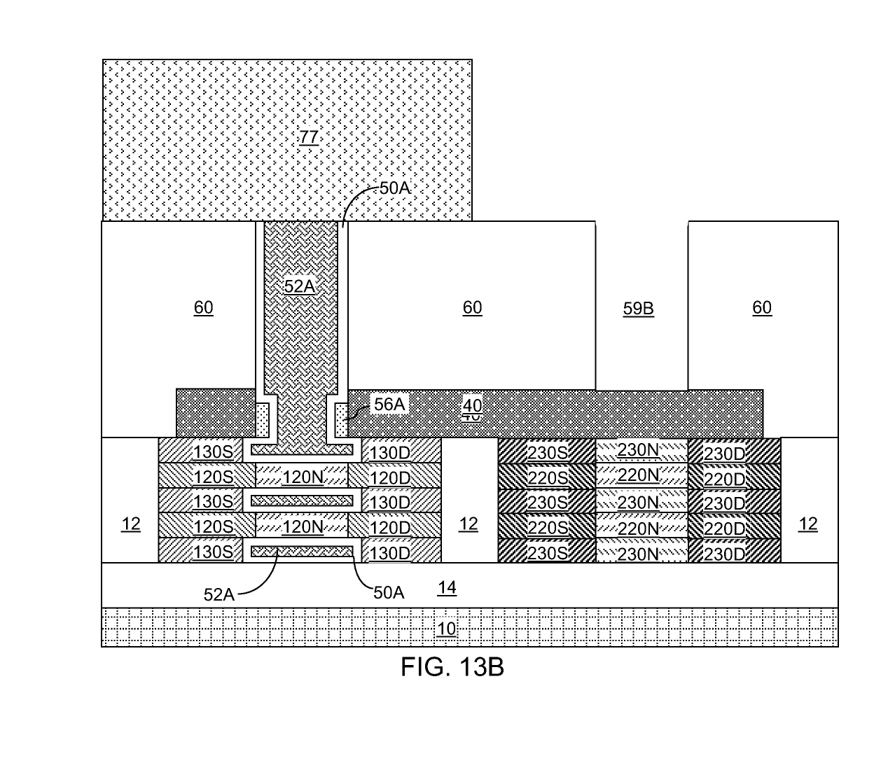

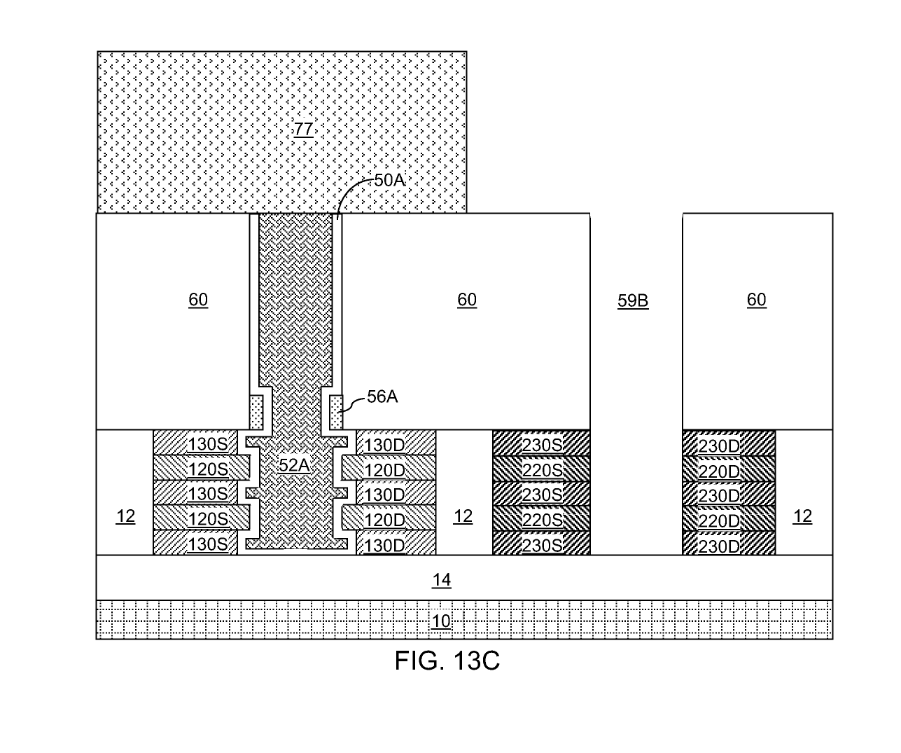

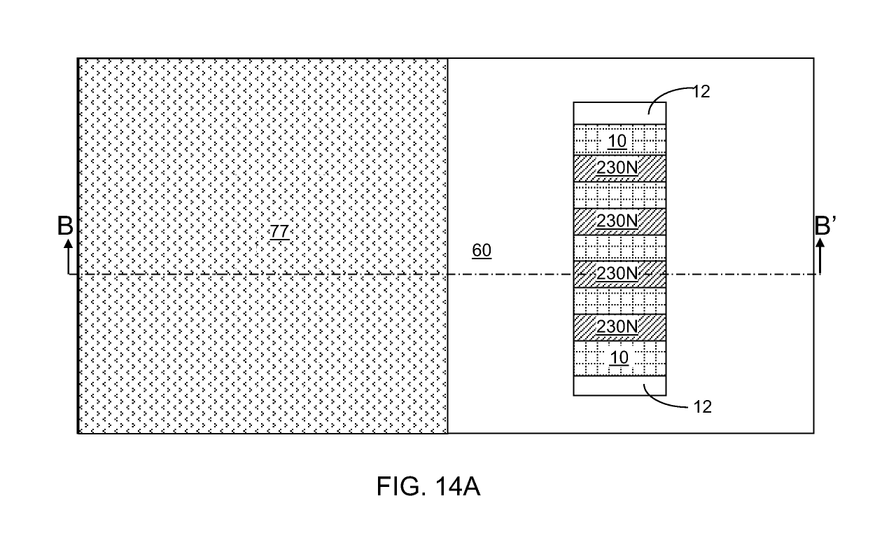

Referring to FIGS. 13A, 13B, and 13C, the second gate cavity 59B is vertically extended downward by anisotropically etching the second alternating stack employing the combination of the planarization dielectric layer 60 and the plurality of fin-defining mask structures 40 as an etch mask. Thus, the second gate cavity 59B is vertically extended only within regions that are not blocked by the plurality of fin-defining mask structures 40. The second gate cavity 59B can be vertically extended downward to the top surface of the insulator layer 14. Optionally, an anisotropic etch or an isotropic etch can be performed to recess physically exposed surfaces of the insulator layer 14. The bottom portion of the lowest exposed 230N layer may be suspended due to this recess or due to isotropic erosion of the insulator layer 14 during subsequent processing.

The remaining portions of the vertical stack of first material second conductivity type layers 220L and second material second conductivity type layers 230L form a plurality of second vertical stacks of nanowires (220N, 230N). Each second vertical stack of nanowires (220N, 230N) includes first material second conductivity type nanowires 220N and second material second conductivity type nanowires 230N. Each first material second conductivity type nanowire 220N includes the silicon-germanium alloy and can have a doping of the second conductivity type, and each second material second conductivity type nanowire 230N includes the germanium-free silicon material and can have a doping of the second conductivity type. A junction is present between the second source region (220S, 230S) and each second vertical stack of nanowires (220N, 230N). Another junction is formed between the second drain region (220D, 230D) and each second vertical stack of nanowires (220N, 230N). In one embodiment, the junctions can be p-n junctions. In another embodiment, the junctions can be between doped semiconductor materials and intrinsic semiconductor materials.

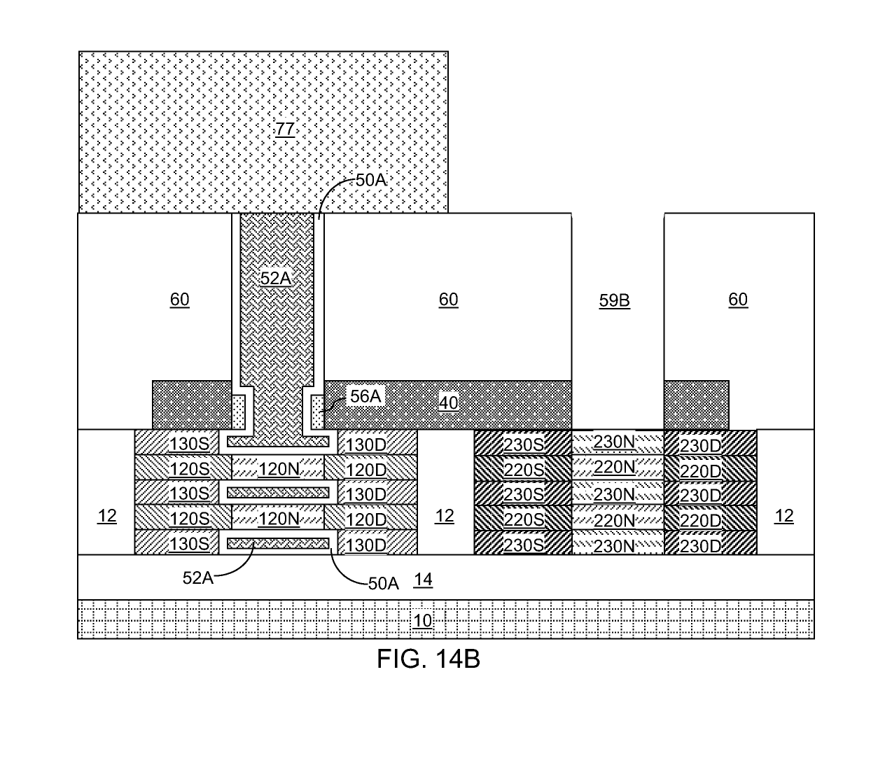

Referring to FIGS. 14A and 14B, physically exposed portions of the plurality of fin-defining mask structures 40 can be optionally removed by an etch, which can be an isotropic etch or an anisotropic etch. The removal of the physically exposed portions of the plurality of fin-defining mask structures 40 is performed selective to the plurality of second vertical stacks of nanowires (220N, 230N). For example, if the plurality of fin-defining mask structures 40 include silicon nitride, the removal of the physically exposed portions of the plurality of fin-defining mask structures 40 can be performed by a wet etch employing hot phosphoric acid. The second masking layer 77, if present, may be removed selective to the first gate electrode 52A, for example, by ashing. Alternately, the second masking layer 77 may remain above the first gate electrode 52A.

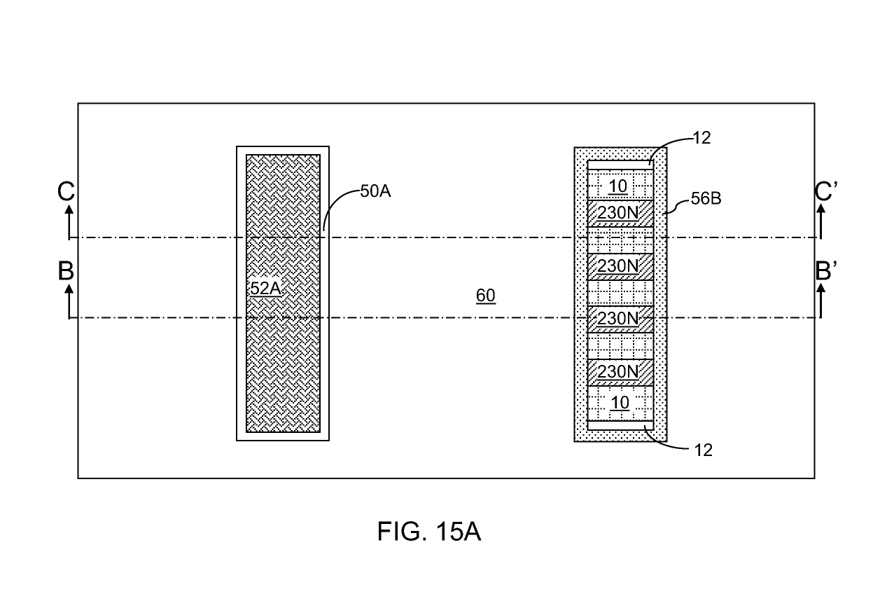

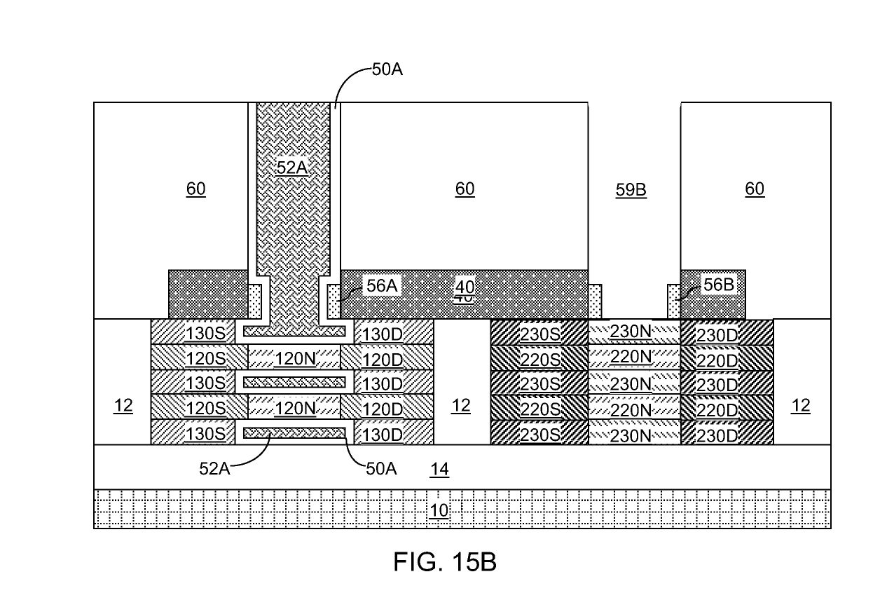

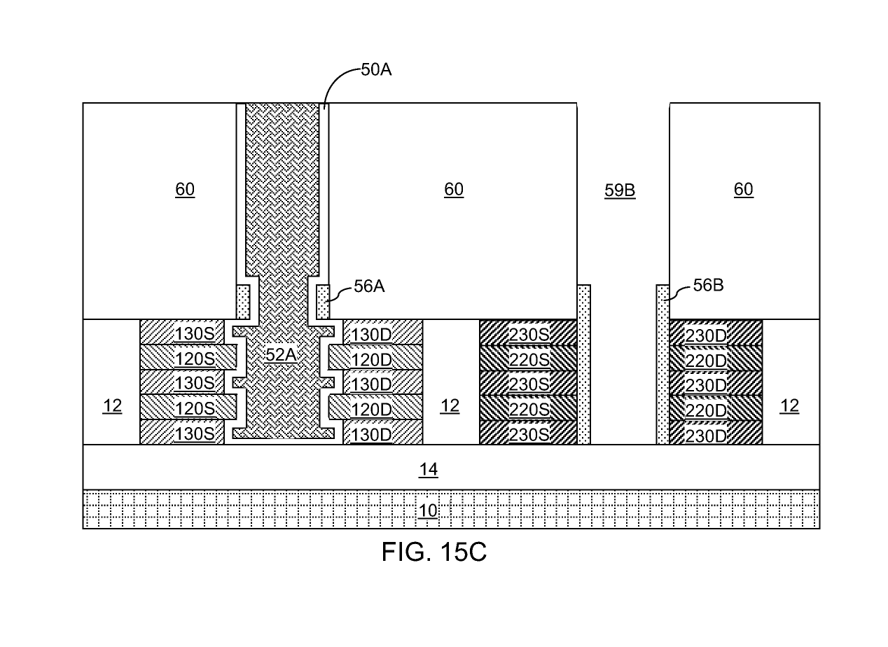

Referring to FIGS. 15A, 15B, and 15C, a second gate spacer 56B can be formed on sidewalls of the planarization dielectric layer 60 within the second gate cavity 59B. For example, a conformal dielectric material layer (not shown) can be deposited, for example, by chemical vapor deposition (CVD) or atomic layer deposition (ALD). The conformal dielectric material layer includes a dielectric material such as silicon nitride, silicon oxide, a dielectric metal oxide, or a combination thereof. The thickness of the conformal dielectric material layer can be from 3 nm to 100 nm, although lesser and greater thicknesses can also be employed.

The dielectric material of the conformal dielectric material layer may, or may not be, the same as the dielectric material of the plurality of fin-defining mask structures 40. In one embodiment, the dielectric material of the conformal dielectric material layer can be the same as the dielectric material of the plurality of fin-defining mask structures 40. In one embodiment, the dielectric material of the conformal dielectric material layer and the dielectric material of the plurality of fin-defining mask structures 40 can be silicon nitride. Vertical portions of the conformal dielectric material layer are subsequently etched by an anisotropic etch to form the second gate spacer 56B.

The second gate spacer 56B including the dielectric material can be formed on the sidewall of the planarization dielectric layer 60 and sidewalls of remaining portions of the plurality of fin-defining mask structures 40 that are present within the vertically extended second gate cavity 59B. The second gate spacers 56B can include at least one vertical strip having a uniform width as illustrated in FIG. 15C. In one embodiment, the uniform width can be the same as the spacing between a neighboring pair of second vertical stacks of nanowires (220N, 230N).

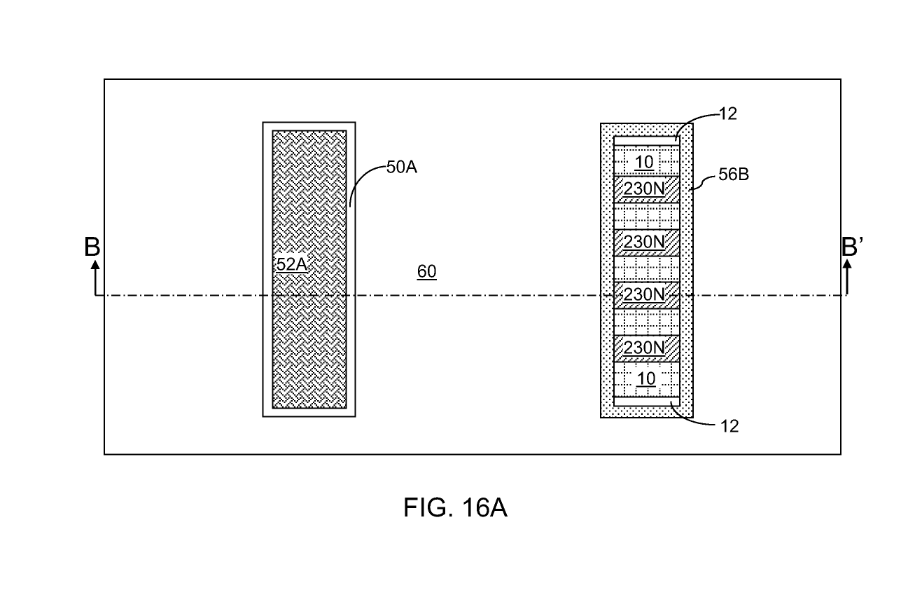

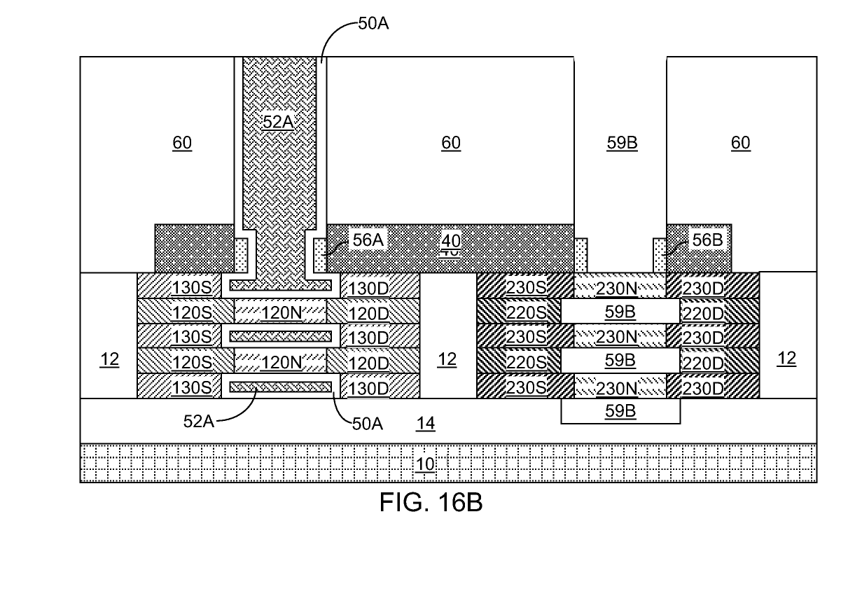

Referring to FIGS. 16A and 16B, a lateral etch of physically exposed portions of the silicon-germanium alloy is performed selective to the germanium-free silicon material. An isotropic dry etch or an isotropic wet etch can be employed for the lateral etch. Thus, the second gate cavity 59B is laterally expanded by removing the silicon-germanium alloy selective to the germanium-free silicon material. The first material second conductivity type nanowires 220N and physically exposed end sub-portions of the first material first source portions 220S and the first material first drain portions 220D are removed by the lateral etch. The second material second conductivity type nanowires 230N become suspended. The second material second conductivity type nanowires 230N constitute a plurality of second suspended semiconductor nanowires, include the germanium-free silicon material, and are located underneath the second gate cavity 59B as formed at the processing step of FIGS. 12A, 12B, and 12C.

In one embodiment, the etch chemistry for the isotropic selective etch of the silicon-germanium alloy selective to the germanium-free silicon material can be a wet etch employing a mixture of hydrofluoric acid and hydrogen peroxide. Alternate etch chemistries for selectively etching a silicon-germanium alloy selective to a germanium-free silicon material as known in the art can also be employed.

Concurrently with removal of the silicon-germanium alloy between second material second conductivity type nanowires 230N, portions of the silicon-germanium alloy are laterally recessed along the lengthwise direction of the second material second conductivity type nanowires 230N. Thus, each nanowire including a second material second conductivity type nanowires 230N is extended along a lengthwise direction to include a portion of a second material second source region 230S and a portion of a second material second drain region 230D. Portions of p-n junctions or portions of junction between doped silicon and intrinsic silicon are physically exposed around each end portion of a semiconductor nanowire including the germanium-free silicon material. The second masking layer 77, if present, may be removed selective to the first gate electrode 52A, for example, by ashing. If the bottom surface of the lowest 230N nanowire channel layer is not already fully suspended as this point, an additional etch of exposed portions of insulator layer 14 may be performed in order to fully suspend the lowest 230N nanowire channel.

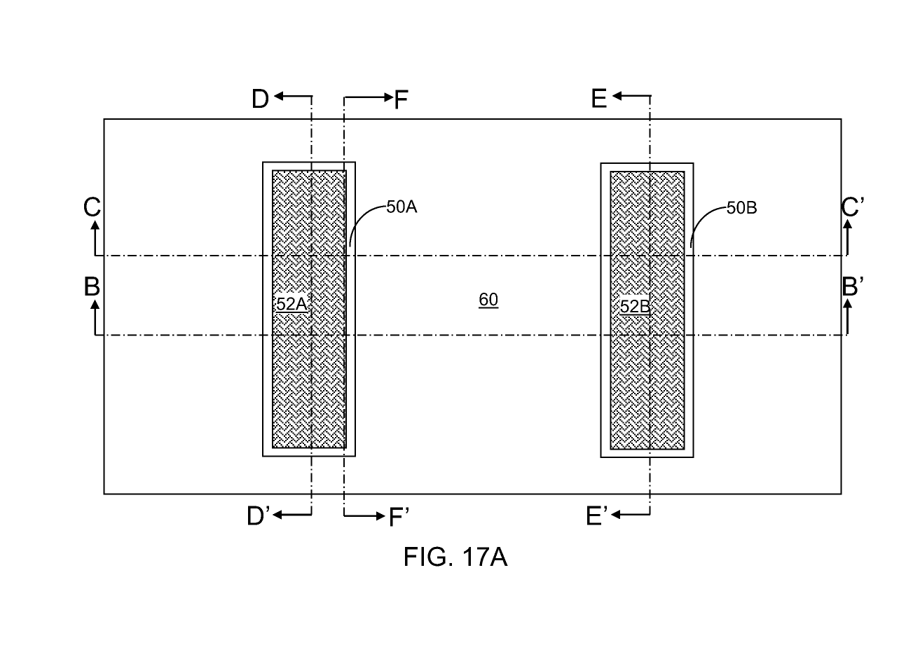

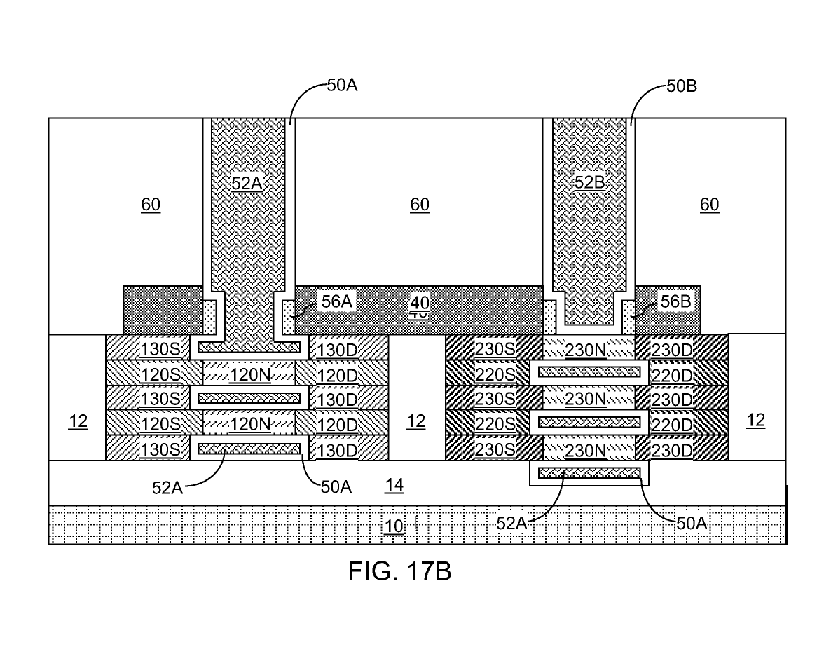

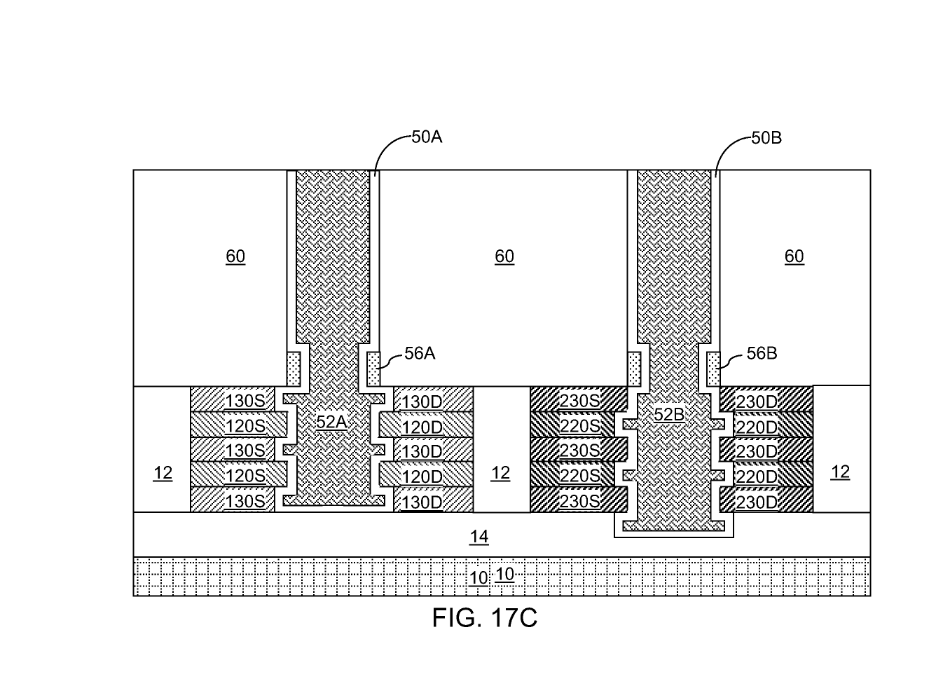

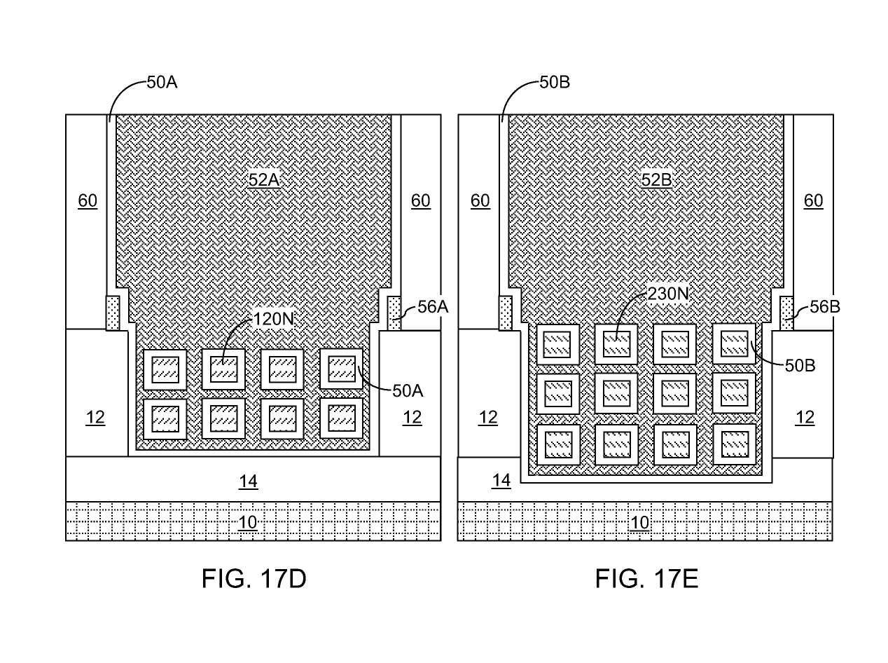

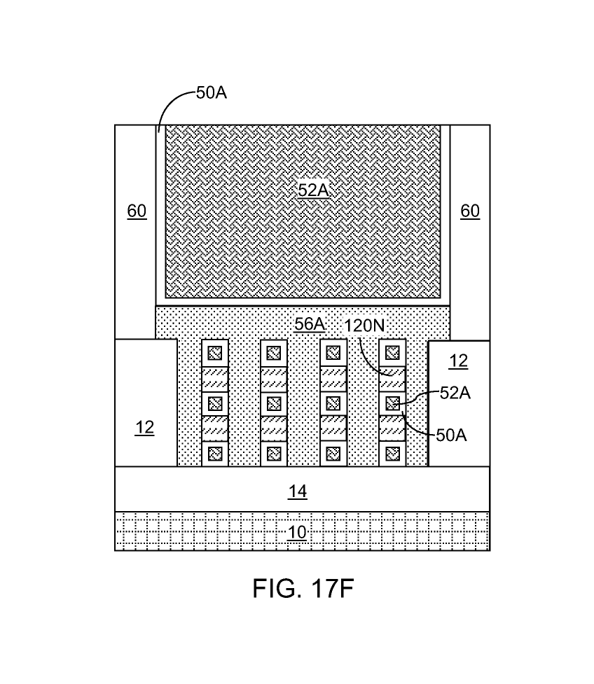

Referring to FIGS. 17A, 17B, 17C, 17D, 17E, and 17F, a second gate dielectric 50B and a second gate electrode 52B are formed within the second gate cavity 59B. The second gate dielectric 50B can be a contiguous structure that extends throughout the second gate cavity 59B. The second gate dielectric 50B and the first gate electrode 52B can be formed by depositing a stack of a gate dielectric layer and a gate conductor layer within the second gate cavity 59B and removing portions of the gate dielectric layer and the gate conductor layer from above a top surface of the planarization dielectric layer 60.

Specifically, the gate dielectric layer can be deposited on physically exposed surfaces within the second gate cavity 59B and on the top surface of the planarization dielectric layer 60. The gate dielectric layer can include any gate dielectric material known in the art. Subsequently, a conductive material is deposited into the second gate cavity 59B. The conductive material, and optionally, the gate dielectric layer are subsequently planarized, for example, by chemical mechanical planarization (CMP). The remaining portion of the gate dielectric layer filling the second gate cavity 59B constitutes the second contiguous gate dielectric 50B, which is contiguous throughout the entirety thereof. The remaining portion of the conductive material filling the second gate cavity 59B constitutes the second gate electrode 52B.

The second gate dielectric 50B is formed on all physically exposed surfaces of the plurality of second semiconductor wires that includes second material second conductivity type nanowires 230N. The second gate electrode 52B is formed on the second gate dielectric 50B and within the second gate cavity 59B.

The second alternating stack, which is a second portion of the alternating stack (20L, 30L; See FIG. 1B), includes various sub-portions. The various sub-portions of the second alternating stack include the second source region (220S, 230S) including a third portion of the alternating stack (20L, 30L), and the second drain region (220D, 230D) including a fourth portion of the alternating stack (20L, 30L).

The exemplary semiconductor structure includes a first field effect transistor and a second field effect transistor. The first transistor includes the first source region (120S, 130S) that contains a first alternating stack of a silicon-germanium alloy and a germanium-free silicon material; a first drain region (120D, 130D) including a second alternating stack of the silicon-germanium alloy and the germanium-free silicon material; a plurality of first channels located within a plurality of first semiconductor nanowires including the silicon-germanium alloy, i.e., the plurality of first material first conductivity type nanowires 120N, and extending between the first source region (120S, 130S) and the first drain region (120D, 130D); and a first gate electrode 52A surrounding each of the first plurality of semiconductor nanowires. The second transistor includes a second source region (220S, 230S) including a third alternating stack of the silicon-germanium alloy and the germanium-free silicon material; a second drain region (220D, 230D) including a fourth alternating stack of the silicon-germanium alloy and the germanium-free silicon material; a plurality of second channels located within a plurality of second semiconductor nanowires including the germanium-free silicon material, i.e., the plurality of second material second conductivity type nanowires 230N, and extending between the second source region (220S, 230S) and the second drain region (220D, 230D); and a second gate electrode 52B surrounding each of the second plurality of semiconductor nanowires.

In one embodiment, the first field effect transistor can be a p-type field effect transistor including a silicon-germanium channel, and the second field effect transistor can be an n-type field effect transistor including a silicon channel. In one embodiment, the silicon-germanium channel of the first field effect transistor can consist of silicon and germanium or can consist of silicon, germanium, and n-type dopants. Additionally, the silicon channel of the second field effect transistor can consist essentially of silicon or consist essentially of silicon and p-type electrical dopants.

The first source region (120S, 130S), the first drain region (120D, 130D), the second source region (220S, 230S), and the second drain region (220D, 230D) are located on the top surface of the insulator layer 14, and have an identical sequence of semiconductor materials from bottom to top, and each semiconductor material layer within the identical sequence is located at a same distance from the top surface across the first source region (120S, 130S), the first drain region (120D, 130D), the second source region (220S, 230S), and the second drain region (220D, 230D). In one embodiment, the first alternating stack, the second alternating stack, the third alternating stack, and the fourth alternating stack includes at least two repetitions of the silicon-germanium alloy and the germanium-free silicon material.

The first source region (120S, 130S) can include first end portions of the plurality of first semiconductor nanowires, and the first drain region (120D, 130D) can include second end portions of the plurality of first semiconductor nanowires. The second source region (220S, 230S) can include first end portions of the plurality of second semiconductor nanowires, and the second drain region (220D, 230D) can include second end portions of the plurality of second semiconductor nanowires.

The first source region (120S, 130S), the first drain region (120D, 130D), the second source region (220S, 230S), and the second drain region (220D, 230D) are vertically spaced from the insulator layer 14.

Due to the lattice mismatch between silicon and germanium, the plurality of first semiconductor nanowires can be under a first type of strain along a lengthwise direction of the plurality of first semiconductor nanowires, and the plurality of second semiconductor nanowires is under a second type of strain along a lengthwise direction of the plurality of second semiconductor nanowires. One of the first type and the second type is compressive, and another of the first type and the second type is tensile.

In one embodiment, one of the first and second field effect transistors can be a p-type field effect transistor, and another of the first and second field effect transistors can be an n-type field effect transistor.

A first gate spacer 56A includes a dielectric material and contacts sidewalls of the first source region (120S, 130S) and sidewalls of the first drain region (120D, 130D). A second gate spacer 56B includes the same dielectric material and contacts sidewalls of the second source region (220S, 230S) and sidewalls of the second drain region (220D, 230D). The first gate spacer 56A includes at least one vertical strip (as illustrated in FIG. 9C) having a uniform width and contacting sidewalls of at least two of the plurality of first semiconductor nanowires. The second gate spacer 56B includes at least one vertical strip (as illustrated in FIG. 15C) having the uniform width and contacting sidewalls of at least two of the plurality of second semiconductor nanowires. The first and second gate spacers (56A, 56B) can be in contact with the insulator layer 14.

The planarization dielectric layer 60 is located over the first source region (120S, 130S), the first drain region (120D, 130D), the second source region (220S, 230S), and the second drain region (220D, 230D) and contacts sidewalls of the first and second gate spacers 56. A top surface of the first gate electrode 52A and a top surface of the second gate electrode 52B can be coplanar with the top surface of the planarization dielectric layer 60.

The first gate electrode 52A includes a plurality of portions that laterally extend underneath the first gate spacer 56 along a lengthwise direction of the plurality of first semiconductor fins. The second gate electrode 52B includes a plurality of portions that laterally extend underneath the second gate spacer 56 along a lengthwise direction of the plurality of second semiconductor fins. The first contiguous gate dielectric 50A contacts the first gate electrode 52A, and the second contiguous gate dielectric 50B contacts the second gate electrode 52B. One of the first contiguous gate dielectric 50A and the second contiguous gate dielectric 50B contacts one of a bottom surface of the first gate spacer 56 and a bottom surface of the second gate spacer 56, i.e., a bottom space of portions of the gate spacers 56 illustrated in FIG. 13C.

The first source region (120S, 130S), the first drain region (120D, 130D), and the first contiguous gate dielectric 50A contact all surfaces of the plurality of first channels included within the first material first conductivity type nanowires 120N. The second source region (220S, 230S), the second drain region (220D, 230D), and the second contiguous gate dielectric 50B contact all surfaces of the plurality of second channels included within the second material second conductivity type nanowires 230N. The insulator layer 14 is in contact with the first source region (120S, 130S), the first drain region (120D, 130D), the second source region (220S, 230S), the second drain region (220D, 230D), the first contiguous gate dielectric 52A, and the second contiguous gate dielectric 52B.

The plurality of first semiconductor nanowires can be a first two-dimensional array of semiconductor nanowires, and the plurality of second semiconductor nanowires can be a second two-dimensional array of semiconductor nanowires. The semiconductor nanowires within the first two-dimensional array of semiconductor nanowires are vertically spaced and laterally spaced along a horizontal direction perpendicular to a lengthwise direction of the plurality of first semiconductor nanowires, and semiconductor nanowires within the second two-dimensional array of semiconductor nanowires are vertically spaced and laterally spaced along a horizontal direction perpendicular to a lengthwise direction of the plurality of second semiconductor nanowires. In one embodiment, each of the first two-dimensional array of semiconductor nanowires and the first two-dimensional array of semiconductor nanowires is a two-dimensional periodic array having a first periodicity along a vertical direction and a second periodicity along a horizontal direction. The first periodicity is the center-to-center distance between a vertically neighboring pair of semiconductor nanowires, and the second periodicity is the center-to-center distance between a laterally neighboring pair of semiconductor nanowires.

While an embodiment in which the first and second disposable gate structures (51A, 51B) are sequentially removed is described herein, a variation is expressly contemplated herein in which the first disposable gate structure 51A and the second disposable gate structure 51B are removed simultaneously. The processing steps of FIGS. 6A, 6B, and 6C are modified not to form the first masking layer 67. In this case, the processing steps of FIGS. 12A, 12B, and 12C can be merged with the processing steps of FIGS. 6A, 6B, and 6C. The processing steps of FIGS. 13A, 13B, and 13C can be merged with the processing steps of FIGS. 7A, 7B, and 7C. The processing steps of FIGS. 14A and 14B can be merged with the processing steps of FIGS. 8A and 8B. The processing steps of FIGS. 15A, 15B, and 15C can be merged with the processing steps of FIGS. 9A, 9B, and 9C. After the processing steps of FIGS. 9A, 9B, and 9C, which form a second gate cavity 59B illustrated in FIGS. 15A, 15B, and 15C in this modified process flow, a first masking layer (which can be a patterned photoresist layer) filling the second gate cavity 59B can be formed. The processing steps of FIGS. 10A and 10B are performed, and the first masking layer can be removed. Subsequently, a second masking layer (which can be a patterned photoresist layer) filling the first gate cavity 59A can be formed. The processing steps of FIGS. 16A and 16B are performed while the second masking layer fills the first gate cavity 59A. After removal of the second masking layer, the processing steps of FIGS. 11A-11F and the processing steps of FIGS. 17A-17F are concurrently performed to form gate dielectrics (50A, 50B) and gate electrodes (52A, 52B).

In another variation, the order of the processing steps between, and including, FIGS. 6A-6C and 11A-11F and the processing steps between, and including, FIGS. 12A-12C and 17A-17F may be reversed.

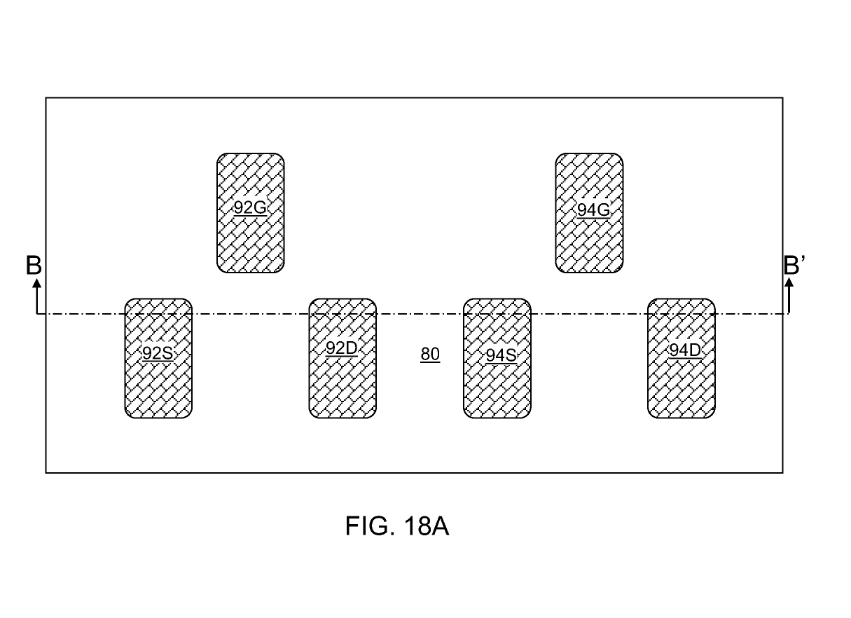

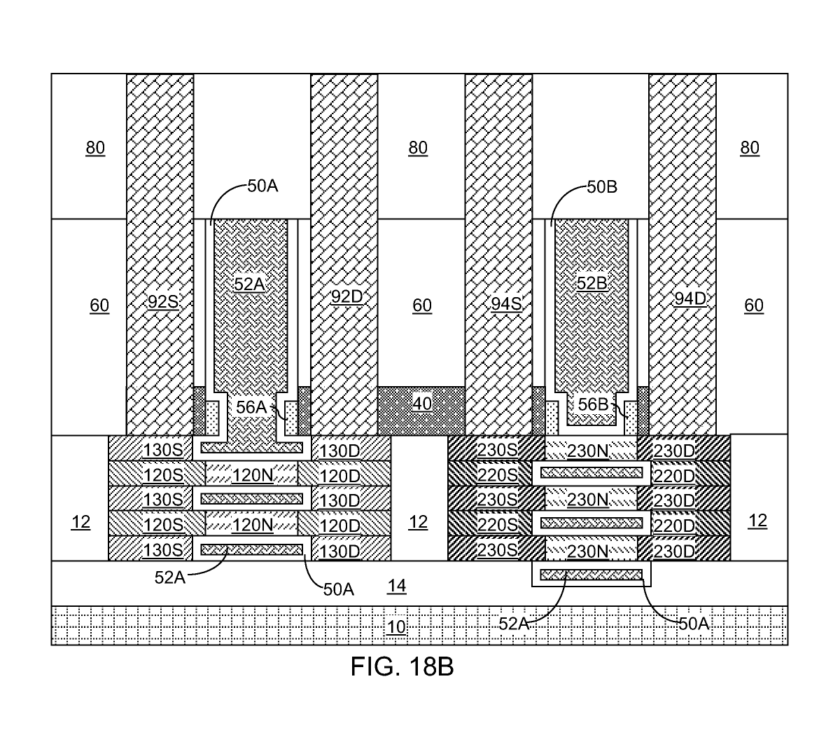

Referring to FIGS. 18A and 18B, a contact level dielectric layer 80 can be formed over the planarization dielectric layer 60. The contact level dielectric layer 80 includes a dielectric material such as silicon oxide, silicon nitride, silicon oxynitride, organosilicate, or combinations of thereof. A first source contact structure 92S, a first drain contact structure 92D, a first gate contact structure 92G, a second source contact structure 94S, a second drain contact structure 94D, and a second gate contact structure 94G can be formed through the contact level dielectric layer 80 to provide electrical contact to the first source region (120S, 130S), the first drain region (120D, 130D), the first gate electrode 52A, the second source region (220S, 230S), the second drain region (220D, 230D), and the second gate electrode 52B, respectively.

The methods of embodiments of the present disclosure can provide two types of nanomesh structures, i.e., a two-dimensional array of nanowires, including two different types of semiconductor materials, i.e., the silicon-germanium alloy and the germanium-free silicon material. The two types of nanomesh structures are collectively referred to as hybrid nanomesh structures. The two different types of semiconductor materials can be selected to independently optimize device performance of p-type field effect transistors including a nanomesh structure of semiconductor nanowires of one of the two semiconductor materials, and n-type field effect transistors including a nanomesh structure of semiconductor nanowires of the other of the two semiconductor materials. Further, the nanomesh structures enable vertical stacking of semiconductor nanowires, and consequent increase of on-current per unit device area.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

What is claimed is:

1. A method of forming a semiconductor structure comprising:
forming an alternating stack of a silicon-germanium alloy and a germanium-free silicon material on an insulator layer;
forming a planarization dielectric layer including a first gate cavity and a second gate cavity over said alternating stack;
forming a plurality of first semiconductor nanowires comprising one of said silicon-germanium alloy and said germanium-free silicon material underneath said first gate cavity by patterning a first portion of said alternating stack; and
forming a plurality of second semiconductor nanowires comprising another of said silicon-germanium alloy and said germanium-free silicon material underneath said second gate cavity by patterning a second portion of said alternating stack.

2. The method of claim 1, further comprising:
forming a plurality of fin-defining mask structures over said alternating stack prior to forming said planarization dielectric layer; and
extending said first gate cavity and said second gate cavity downward by etching said alternating stack employing a combination of said planarization dielectric layer and said plurality of fin-defining mask structures as an etch mask.

3. The method of claim 2, wherein said patterning of said first portion of said alternating stack comprises laterally expanding said first gate cavity by removing said germanium-free silicon material selective to said silicon-germanium alloy while an etch-resistant material portion masks said second portion of said alternating stack.

4. The method of claim 3, wherein said lateral expansion of said first gate cavity is performed by an isotropic etch, and said etch-resistant material portion is a photoresist portion.

5. The method of claim 3, further comprising forming p-n junctions within said first portion of said alternating stack, wherein said forming of said plurality of first semiconductor nanowires comprises removing portion of said germanium-free silicon material to physically expose portions of said p-n junctions within said silicon-germanium alloy.

6. The method of claim 3, wherein said patterning of said second portion of said alternating stack comprises laterally expanding said second gate cavity by removing said silicon-germanium alloy selective to said germanium-free silicon material while another etch-resistant material portion masks said second portion of said alternating stack.

7. The method of claim 1, further comprising:
forming a first disposable gate structure over said first portion of said alternating stack and a second disposable gate structure over said second portion of said alternating stack;
depositing and planarizing a dielectric material over said first and second disposable gate structures; and
removing said first and second disposable gate structures selective to said deposited and planarized dielectric material, wherein said deposited and planarized dielectric material constitutes said planarization dielectric layer including said first gate cavity and said second gate cavity.

8. The method of claim 7, further comprising:
forming a plurality of fin-defining mask structures over said alternating stack, wherein said first and second disposable gate structures are formed over said plurality of fin-defining mask structures; and
extending said first gate cavity and said second gate cavity downward by etching said alternating stack employing a combination of said planarization dielectric layer and said plurality of fin-defining mask structures as an etch mask.

9. The method of claim 1, further comprising:
providing a dopant of a first conductivity type to said first portion of said alternating stack prior to said forming of said planarization dielectric layer; and
providing a dopant of a second conductivity type that is the opposite of said first conductivity type to said second portion of said alternating stack.

10. The method of claim 9, further comprising:
forming a first disposable gate structure over said first portion of said alternating stack and a second disposable gate structure over said second portion of said alternating stack;
doping sub-portions of said first portion of said alternating stack with dopants of said second conductivity type employing said first disposable gate structure as an implantation mask; and
doping sub-portions of said second portion of said alternating stack with dopants of said first conductivity type employing said second disposable gate structure as an implantation mask.

11. The method of claim 10, wherein said sub-portions of said first portion of said alternating stack comprises:
a first source region comprising a first portion of said alternating stack; and
a first drain region comprising a second portion of said alternating stack, and said sub-portions of said second portion of said alternating stack comprises:
a second source region comprising a third portion of said alternating stack; and
a second drain region comprising a fourth portion of said alternating stack.

12. The method of claim 1, wherein an entirety of said alternating stack is single crystalline upon formation.

13. A semiconductor structure comprising a first field effect transistor and a second field effect transistor,
wherein said first field effect transistor comprises:
a first source region comprising a first alternating stack of a silicon-germanium alloy and a germanium-free silicon material;
a first drain region comprising a second alternating stack of said silicon-germanium alloy and said germanium-free silicon material;
a plurality of first channels located within a plurality of first semiconductor nanowires comprising said silicon-germanium alloy and extending between said first source region and said first drain region; and
a first gate electrode surrounding each of said first plurality of semiconductor nanowires, and wherein said second field effect transistor comprises:
a second source region comprising a third alternating stack of said silicon-germanium alloy and said germanium-free silicon material;
a second drain region comprising a fourth alternating stack of said silicon-germanium alloy and said germanium-free silicon material;
a plurality of second channels located within a plurality of second semiconductor nanowires comprising said germanium-free silicon material and extending between said second source region and said second drain region; and
a second gate electrode surrounding each of said second plurality of semiconductor nanowires.

14. The semiconductor structure of claim 13, wherein said first source region, said first drain region, said second source region, and said second drain region are in contact with an insulator layer.

15. The semiconductor structure of claim 13, wherein said first source region, said first drain region, said second source region, and said second drain region are single crystalline.

16. The semiconductor structure of claim 15, wherein said germanium-free silicon material consists essentially of silicon and optional dopants of p-type or n-type.

17. The semiconductor structure of claim 15, wherein said plurality of first semiconductor nanowires is under a first type of strain along a lengthwise direction of said plurality of first semiconductor nanowires, and said plurality of second semiconductor nanowires is under a second type of strain along a lengthwise direction of said plurality of second semiconductor nanowires, wherein one of said first type and said second type is compressive, and another of said first type and said second type is tensile.

18. The semiconductor structure of claim 14, wherein each of said plurality of first channels and said plurality of second channels comprises an intrinsic semiconductor material.

19. The semiconductor structure of claim 13, wherein said first source region comprises first end portions of said plurality of first semiconductor nanowires, said first drain region comprises second end portions of said plurality of first semiconductor nanowires, said second source region comprises first end portions of said plurality of second semiconductor nanowires, and said second drain region comprises second end portions of said plurality of second semiconductor nanowires.

20. The semiconductor structure of claim 19, further comprising:
a first gate spacer comprising a dielectric material and contacting a sidewall of said first source region and a sidewall of said first drain region; and
a second gate spacer comprising said dielectric material and contacting a sidewall of said second source region and a sidewall of said second drain region.

21. The semiconductor structure of claim 20, wherein said first gate spacer comprises at least one vertical strip having a uniform width and contacting sidewalls of at least two of said plurality of first semiconductor nanowires, and said second gate spacer comprises at least one vertical strip having said uniform width and contacting sidewalls of at least two of said plurality of second semiconductor nanowires.

22. The semiconductor structure of claim 21, wherein said first source region, said first drain region, said second source region, and said second drain region are in contact with an insulator layer, and said first and second gate spacers are in contact with said insulator layer.

23. The semiconductor structure of claim 20, further comprising a planarization dielectric layer located over said first source region, said first drain region, said second source region, and said second drain region and contacting sidewalls of said first and second gate spacers.

24. The semiconductor structure of claim 23, wherein a top surface of said first gate electrode and a top surface of said second gate electrode are coplanar with a top surface of said planarization dielectric layer.

25. The semiconductor structure of claim 20, wherein said first gate electrode includes a plurality of portions that laterally extend underneath said first gate spacer along a lengthwise direction of said plurality of first semiconductor fins, and said second gate electrode includes a plurality of portions that laterally extend underneath said second gate spacer along a lengthwise direction of said plurality of second semiconductor fins.
